(19) United States
(12) Patent Application Publication
(10) Pub. No.: US 2026/0128570 A1
(43) Pub. Date: May 7, 2026

(54) OPTICAL INTEGRATED DEVICE AND METHOD FOR MANUFACTURING OPTICAL INTEGRATED DEVICE

(71) Applicant: Mitsubishi Electric Corporation, Tokyo (JP)

(72) Inventors: Keita MOCHIZUKI, Tokyo (JP); Harunaka YAMAGUCHI, Tokyo (JP); Kazumasa KISHIMOTO, Tokyo (JP)

(73) Assignee: Mitsubishi Electric Corporation, Tokyo (JP)

(21) Appl. No.: 19/109,817

(22) PCT Filed: Nov. 9, 2022
(86) PCT No.: PCT/JP2022/041644

§ 371 Date: Mar. 7, 2025

(51) Int. Cl. H01S 5/20; H01S 5/22

(52) U.S. Cl. CPC H01S 5/2031; H01S 5/22

(57) ABSTRACT

An optical integrated device that integrates an optical functional element and an optical circuit element according to the present disclosure includes: the optical functional element comprising a protruding-shaped high-mesa section that includes a part of the compound semiconductor substrate and comprises an active layer and a contact layer, and planar-shaped terrace portions positioned at a predetermined height with respect to the active layer, an optical circuit element comprising a lower cladding layer, a core layer and an upper cladding layer formed above the semiconductor substrate, a first recess and second recesses, wherein the optical functional element and the optical circuit element are flip-chip mounted.

### TECHNICAL FIELD

This disclosure relates to an optical integrated device and a method for manufacturing an optical integrated device.

### BACKGROUND ART

In recent years, silicon photonics technology, which integrates optical functional elements on silicon (Si) substrates, has attracted attention in the field of optical devices such as communications. Silicon photonics technology allows the mature silicon substrate processing technology developed in the manufacture of electronic circuits to be diverted to manufacturing. In addition, since silicon has a refractive index higher than that of glass, which is generally used as an optical element, it is possible to confine light in a small area, and thus, it is expected to achieve large-scale optical integrated devices that are inexpensive and miniaturized.

In optical semiconductor devices made of various materials such as indium phosphide (InP), gallium arsenide (GaAs), gallium nitride (GaN), lithium niobate (LiNbO₃), and compound semiconductors including these materials, the optical waveguide is the most basic component that can locally confine light to a specific region by increasing the refractive index higher than that of the surrounding area, and propagate light to a desired region by forming such specific region in a linear shape, that is, a striped shape. In optical integrated devices made of semiconductors including silicon optical circuit elements, a large-scale optical integrated device with various functions can be achieved by interconnecting functional blocks such as semiconductor lasers, optical receivers, modulators, and optical filters with the above-mentioned optical waveguides.

Unfortunately, there is a significant problem with using silicon optical circuit elements as optical semiconductor devices. That is, since silicon is an indirect transition semiconductor, the interaction between electrons and light is limited, and thus, it is difficult to achieve active functions such as semiconductor lasers and optical amplifiers by silicon alone. Consequently, direct transition semiconductors, such as InP and other compound semiconductors, are essential as the constituent materials for achieving active functions.

Accordingly, in silicon photonics technology, integration technology to achieve passive functions and active functions using different materials is widely studied. Monolithic integration of silicon and compound semiconductor materials on the same substrate using epitaxial crystal growth is difficult due to the difference of lattice constants between silicon and compound semiconductor materials. Consequently, currently, so-called hybrid integrated structures in which active functional elements (Hereinafter referred to as optical functional element) made of compound semiconductor materials are mounted and integrated on silicon optical circuit elements are widely applied. In the following description, silicon optical circuit elements and optical functional elements may be collectively referred to simply as optical elements.

Various types of hybrid integrated structures between silicon optical circuit elements and optical functional elements have been proposed. As an example of the hybrid integrated structures, for example, there is a butt coupling method in which the silicon optical circuit elements and optical functional elements, each of which has the above-described optical waveguides extending to the optical end faces, are arranged in close proximity so that the cross sections of the respective optical waveguides on the end faces of the respective optical elements face each other, so that light propagating in one optical element is introduced into the other optical element through a free space.

As another example of the hybrid integrated structures, there is a grating coupler method in which light propagating in the optical waveguides formed on the silicon optical circuit elements or optical functional elements is reflected in the vertical direction of the optical element by a grating, and then, the light is introduced into the optical waveguide of the other optical element through a grating formed on the other optical element arranged opposite to the optical element.

Furthermore, there is a bonding method in which the silicon optical circuit elements and optical functional elements are physically bonded in such a way that the optical waveguides of both run very close to each other, and light propagating in one optical element is introduced into the other optical element by evanescent waves.

Unfortunately, in the butt coupling method, the cross-sectional size of a typical optical waveguide in the silicon optical circuit element and the optical functional element is small, from sub-micron to several microns at most. Consequently, in the case where the mounting positions of the silicon optical circuit element and the optical functional element are slightly misaligned, the light emitted from one optical element cannot be successfully introduced into the other optical element, resulting in a large loss of optical power.

In order to reduce the misalignment of the mounting positions of the two optical elements, a technology has been developed to precisely adjust the relative positions of the optical elements in the in-plane direction using alignment marks. Unfortunately, the method using alignment marks does not guarantee the accuracy in the vertical direction, that is, the height direction, of the optical element surface, and thus the manufacturing error of each optical element directly affects the optical coupling efficiency.

The mounting accuracy of the optical element described above typically requires sub-micron level accuracy in both the in-plane and the vertical direction, that is, the height direction, of the optical element. The grating coupler method can expand the size of the light distribution using a grating, so that the mounting accuracy of the optical element can be reduced by about one order of magnitude compared to the butt coupling method. Unfortunately, the grating coupler method has the disadvantage that the optical coupling loss also fluctuates depending on the polarization and wavelength of the propagating light, because the grating has polarization dependence and wavelength dependence.

The bonding method requires that optical elements or wafers made of different materials are bonded together, thus wafer manufacturing technology that is free of dust and particles, as well as bonding processes, are essential, requiring extremely high manufacturing precision.

In this disclosure, attention will be paid to the butt coupling method, which can be manufactured relatively easily among the above-mentioned methods and can achieve both low polarization dependence and low wavelength dependence.

As a technology for solving the problem of positional accuracy in the vertical direction of the surface of the silicon optical circuit element and the optical functional element in the butt coupling method, for example, Patent Document 1 discloses a technology for improving the relative positional accuracy in the vertical direction, that is, the height direction, between two optical elements by forming an etching stop layer, in which a chemical reaction different from that of the surrounding layer occurs, between the core layer and the substrate layer in an optical functional element, and contacting a surface defined on the basis of the etching stop layer with a surface on a silicon optical circuit element. That is, forming an etching stop layer in the epitaxial crystal growth process on a compound semiconductor substrate enables the relative distance between the core layer and etching stop layer to be controlled with high accuracy. This technique achieves highly efficient optical coupling between silicon optical circuit elements and optical functional elements.

### CITATION LIST

### Patent Document

Patent Document 1: Japanese U.S. Pat. No. 6,696,151

### SUMMARY OF THE INVENTION

### Problem to be Solved by the Invention

Patent Document 1 discloses a manufacturing technology and an element structure utilizing an etching stop layer to improve the accuracy of the relative positions of silicon optical circuit elements and optical functional elements in the vertical direction, that is, in the height direction. The manufacturing technology and the element structure described in Patent Document 1 utilize an etching stop layer to achieve higher precision, but there is a problem that in the case where an etching stop layer is formed close to the core layer (active layer) where light propagates, the propagating light mode is deformed, and thus optical loss occurs during propagation or when light is coupled between different optical elements.

There is also a concern that the etching stop layer, which is made of a different material to the surrounding layers, prevents the smooth movement of carriers such as electrons and holes. Furthermore, since the energy distribution of the propagation light mode is generally localized on the side of the semiconductor substrate having a high equivalent refractive index, the influence of the phenomenon that the propagation light mode is deformed is larger when the etching stop layer is located on the side of the semiconductor substrate.

In order to avoid the above-mentioned problem, the core layer (active layer) and the etching stop layer require a certain distance therebetween, or even if the etching stop layer is close to the core layer (active layer), the etching stop layer is required to located on the surface side opposite the semiconductor substrate when viewed from the core layer. These problems are more pronounced in so-called high-mesa structures, where the core layer (active layer) and the upper and lower contact layers are etched to narrow the width of the core layer (active layer) as a light waveguide structure for optical functional elements. This is because the optical waveguide structure called the high-mesa structure confines light and carriers to a smaller area.

The present disclosure has been made in order to solve the above-mentioned problems, and it is an object of the present disclosure to provide an optical integrated device and a method for manufacturing an optical integrated device that improves the relative positional accuracy in the vertical direction, that is, in height direction, of the surfaces of optical circuit elements and optical functional elements, so that even when the optical functional element has a high-mesa structure, it is possible to prevent excessive optical loss, and the like.

### Means to Solve the Problem

The optical integrated device according to the present disclosure is the optical integrated device that integrates an optical functional element and an optical circuit element, the optical integrated device comprising:
an optical functional element, the optical functional element including:
a compound semiconductor substrate;
a protruding-shaped high-mesa section that includes a part of the compound semiconductor substrate, the high-mesa section including at least an active layer and a contact layer from the side of the compound semiconductor substrate; and
planar-shaped terrace portions that are provided along the high-mesa section and are positioned at a predetermined height with respect to the active layer,
an optical circuit element, the optical circuit element including:
a semiconductor substrate;
a stacked structure substrate including a lower cladding layer, a core layer and an upper cladding layer formed above the semiconductor substrate;
a first recess provided in the stacked structure substrate;
second recesses each provided along two opposing side surfaces of the first recess at a predetermined distance from the side surfaces;
an optical waveguide section including the lower cladding layer, the core layer and the upper cladding layer, the optical waveguide section being provided in contact with the side surface different from the two side surfaces of the first recess, wherein
each terrace portion of the optical functional element is in contact with each top of the protrusion portions formed between the first recess and each second recesses of the optical circuit element,
the top surface of the high-mesa section is bonded to the bottom of the first recess, and
the active layer of the high-mesa section is optically coupled to the core layer of the optical waveguide section.

A method for manufacturing an optical integrated device according to the present disclosure is a method for manufacturing an optical integrated device that integrates an optical functional element and an optical circuit element having a first recess and second recesses, the method for manufacturing an optical integrated device comprising:
a step of manufacturing the optical functional element, the step of manufacturing the optical functional element including: a step of successively epitaxially growing an active layer and a contact layer above a compound semiconductor substrate; a step of forming, by etching, a protruding-shaped high-mesa section that includes a part of the compound semiconductor substrate, the high-mesa section including at least the active layer and the contact layer from the side of the compound semiconductor substrate; and a step of forming terrace portions by wet etching using a mixed solution of tartaric acid and hydrogen peroxide as an etchant, each terrace portion being exposed the outermost surface of the compound semiconductor substrate,
a step of flip-chip mounting the optical functional element and the optical circuit element by contacting each terrace portion of the optical functional element with each top of protrusion portions formed between the first recess and each second recess of the optical circuit element, and bonding the top surface of the high-mesa section to the bottom of the first recess of the optical circuit element.

### Effect of the Invention

In the optical integrated device and the method for manufacturing the optical integrated device according to the present disclosure, the surfaces of the terrace portions of the optical functional element are formed so as to be positioned at a predetermined height with respect to the active layer, thereby the relative positional misalignment between the optical functional element and the optical circuit element in the height direction can be precisely controlled, thus providing an effect of achieving the optical integrated device with high optical coupling efficiency and the method for manufacturing the optical integrated device.

### BRIEF DESCRIPTION OF THE DRAWINGS

FIG. 1 is an overview diagram showing a structure of an optical integrated device according to Embodiment 1;

FIG. 2 is a top view showing the structure of the optical integrated device according to Embodiment 1;

FIG. 3 is an overview diagram showing the optical integrated device according to Embodiment 1 as viewed from a cross section along line A in FIG. 1;

FIG. 4 is a cross-sectional view along line A in FIG. 1 for the optical integrated device according to Embodiment 1;

FIG. 5 is a cross-sectional view along line B in FIG. 1 for the optical integrated device according to Embodiment 1;

FIG. 6 is a cross-sectional view along line C in FIG. 1 for the optical integrated device according to Embodiment 1;

FIG. 7A is a cross-sectional view showing a method for manufacturing an optical integrated device according to Embodiment 1;

FIG. 7B is a cross-sectional view showing the method for manufacturing an optical integrated device according to Embodiment 1;

FIG. 7C is a cross-sectional view showing the method for manufacturing an optical integrated device according to Embodiment 1;

FIG. 7D is a cross-sectional view showing the method for manufacturing an optical integrated device according to Embodiment 1;

FIG. 7E is a cross-sectional view showing the method for manufacturing an optical integrated device according to Embodiment 1;

FIG. 7F is a cross-sectional view showing the method for manufacturing an optical integrated device according to Embodiment 1; FIG. 7G is a cross-sectional view showing the method for manufacturing an optical integrated device according to Embodiment 1;

FIG. 7H is a cross-sectional view showing the method for manufacturing an optical integrated device according to Embodiment 1;

FIG. 8 is a diagram showing the relationship between optical coupling efficiency and positional misalignment in the optical integrated device according to Embodiment 1;

FIG. 9 is a diagram showing the relationship between optical coupling efficiency and positional misalignment in the optical integrated device according to Embodiment 1;

FIG. 10 is a top view showing the structure of an optical integrated device according to Modification of Embodiment 1;

FIG. 11 is a cross-sectional view along line A in FIG. 10 for the optical integrated device according to Modification of Embodiment 1;

FIG. 12 is a cross-sectional view along line B in FIG. 10 for the optical integrated device according to Modification of Embodiment 1;

FIG. 13 is an overview diagram showing a structure of an optical integrated device according to Embodiment 2;

FIG. 14 is a top view showing the structure of the optical integrated device according to Embodiment 2;

FIG. 15 is an overview diagram showing the optical integrated device according to Embodiment 2 as viewed from a cross section along line A in FIG. 13;

FIG. 16 is a cross-sectional view along line A in FIG. 13 for the optical integrated device according to Embodiment 2;

FIG. 17 is a cross-sectional view along line B in FIG. 13 for the optical integrated device according to Embodiment 2;

FIG. 18 is a cross-sectional view along line C in FIG. 13 for the optical integrated device according to Embodiment 2;

FIG. 19A is a cross-sectional view showing a method for manufacturing an optical integrated device according to Embodiment 2;

FIG. 19B is a cross-sectional view showing the method for manufacturing an optical integrated device according to Embodiment 2;

FIG. 19C is a cross-sectional view showing the method for manufacturing an optical integrated device according to Embodiment 2;

FIG. 19D is a cross-sectional view showing the method for manufacturing an optical integrated device according to Embodiment 2;

FIG. 19E is a cross-sectional view showing the method for manufacturing an optical integrated device according to Embodiment 2;

FIG. 19F is a cross-sectional view showing the method for manufacturing an optical integrated device according to Embodiment 2;

FIG. 19G FIG. 19F is a cross-sectional view showing the method for manufacturing an optical integrated device according to Embodiment 2;

FIG. 19H is a cross-sectional view showing the method for manufacturing an optical integrated device according to Embodiment 2;

FIG. 20 is a top view showing a structure of an optical integrated device according to Modification of Embodiment 2;

FIG. 21 is a cross-sectional view along line A in FIG. 20 for the optical integrated device according to Modification of Embodiment 2;

FIG. 22 is a cross-sectional view along line B in FIG. 20 for the optical integrated device according to Modification of Embodiment 2;

FIG. 23 is an overview diagram showing a structure of an optical integrated device according to Embodiment 3;

FIG. 24 is a top view showing the structure of the optical integrated device according to Embodiment 3;

FIG. 25 is an overview diagram showing the optical integrated device according to Embodiment 3 as viewed from a cross section along line A in FIG. 19;

FIG. 26 is a cross-sectional view along line A in FIG. 19 for the optical integrated device according to Embodiment 3;

FIG. 27 is a cross-sectional view along line B in FIG. 19 for the optical integrated device according to Embodiment 3;

FIG. 28 is a cross-sectional view along line C in FIG. 19 for the optical integrated device according to Embodiment 3;

FIG. 29A is a cross-sectional view showing an method for manufacturing an optical integrated device according to Embodiment 3;

FIG. 29B is a cross-sectional view showing the method for manufacturing the optical integrated device according to Embodiment 3;

FIG. 29C is a cross-sectional view showing the method for manufacturing the optical integrated device according to Embodiment 3;

FIG. 29D is a cross-sectional view showing the method for manufacturing the optical integrated device according to Embodiment 3;

FIG. 29E is a cross-sectional view showing the method for manufacturing the optical integrated device according to Embodiment 3;

FIG. 29F is a cross-sectional view showing the method for manufacturing the optical integrated device according to Embodiment 3;

FIG. 29G is a cross-sectional view showing the method for manufacturing the optical integrated device according to Embodiment 3;

FIG. 30 is a top view showing a structure of an optical integrated device according to Modification of Embodiment 3;

FIG. 31 is a cross-sectional view along line A in FIG. 30 for the optical integrated device according to Modification of Embodiment 3;

FIG. 32 is a cross-sectional view along line B in FIG. 30 for the optical integrated device according to Modification of Embodiment 3;

FIG. 33 is an overview diagram showing a structure of an optical integrated device according to Embodiment 4;

FIG. 34 is a top view showing a structure of the optical integrated device according to Embodiment 4;

FIG. 35 is an overview diagram showing the optical integrated device according to Embodiment 4 as viewed from a cross section along line A in FIG. 33;

FIG. 36 is a cross-sectional view along line A in FIG. 33 for the optical integrated device according to Embodiment 4;

FIG. 37 is a cross-sectional view along line B in FIG. 33 for the optical integrated device according to Embodiment 4;

FIG. 38 is a cross-sectional view along line C in FIG. 33 for the optical integrated device according to Embodiment 4;

FIG. 39 is a top view showing the structure of an optical integrated device according to Modification of Embodiment 4;

FIG. 40 is a cross-sectional view along line A in FIG. 39 for the optical integrated device according to Modification of Embodiment 4;

FIG. 41 is a cross-sectional view along line B in FIG. 39 for the optical integrated device according to Modification of Embodiment 4;

FIG. 42 is an overview diagram showing a structure of an optical integrated device according to Embodiment 5;

FIG. 43 is a top view showing the structure of an optical integrated device according to Embodiment 5;

FIG. 44 is a cross-sectional view along line A in FIG. 42 for the optical integrated device according to Embodiment 5;

FIG. 45 is a cross-sectional view along line B in FIG. 42 for the optical integrated device according to Embodiment 5;

FIG. 46 is a cross-sectional view along line C in FIG. 42 for the optical integrated device according to Embodiment 5;

FIG. 47 is a top view showing the structure of an optical integrated device according to Modification of Embodiment 5;

FIG. 48 is a cross-sectional view along line A in FIG. 47 for the optical integrated device according to Modification of Embodiment 5;

FIG. 49 is a cross-sectional view along line B in FIG. 47 for the optical integrated device according to Modification of Embodiment 5;

FIG. 50 is a cross-sectional view of an optical integrated device according to Embodiment 6;

FIG. 51 is a cross-sectional view of an optical integrated device according to Embodiment 7.

### DESCRIPTION OF EMBODIMENTS

### Embodiment 1

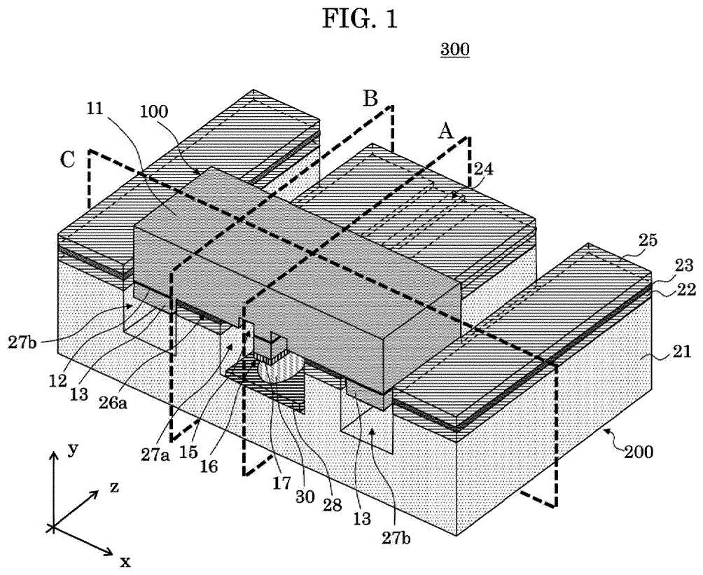

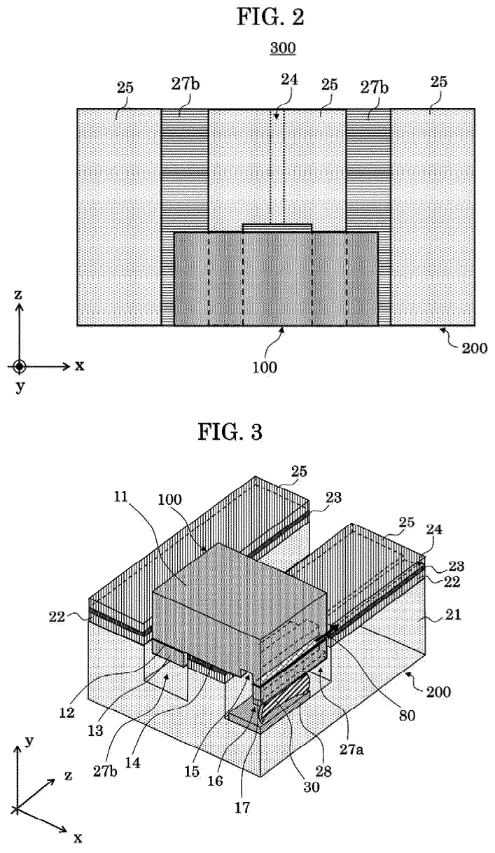

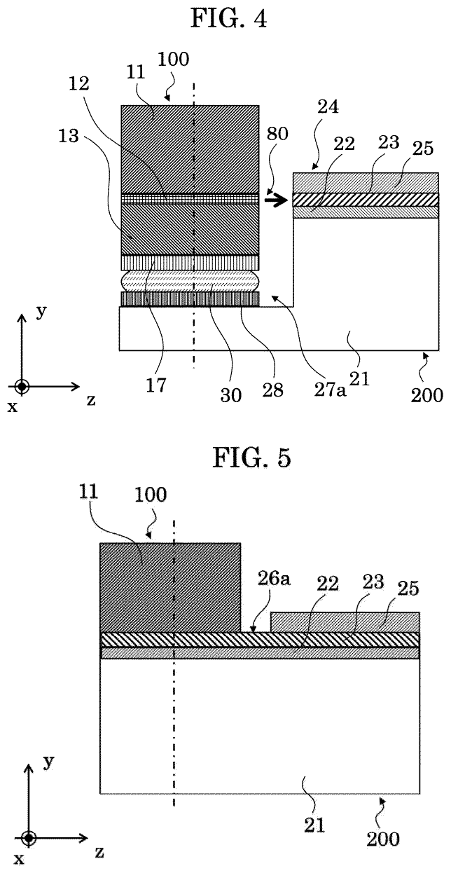

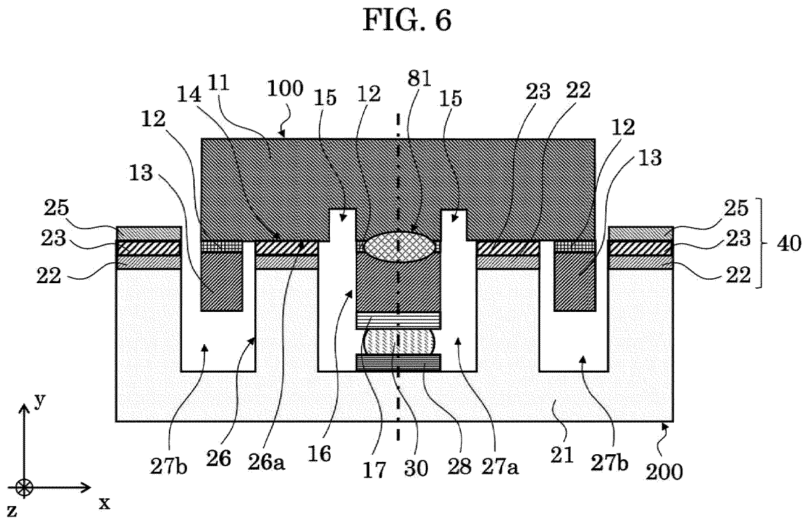

FIG. 1 is an overview diagram showing a structure of an optical integrated device 300 according to Embodiment 1. FIG. 2 is a top view showing the structure of the optical integrated device 300 according to Embodiment 1. FIG. 3 is an overview diagram showing the optical integrated device 300 according to Embodiment 1 as viewed from a cross section along line A in FIG. 1. FIG. 4 is a cross-sectional view along line A in FIG. 1 for the optical integrated device 300 according to Embodiment 1. FIG. 5 is a cross-sectional view along line B in FIG. 1 for the optical integrated device 300 according to Embodiment 1. FIG. 6 is a cross-sectional view along line C in FIG. 1 for the optical integrated device 300 according to Embodiment 1. In FIGS. 1 to 6, the xyz axis directions are shown for convenience of explanation. FIG. 6 schematically shows the spread 81 of the optical mode propagating through a high-mesa section 16 of an optical functional element 100.

### Configuration of Optical Integrated Device According to Embodiment 1

The optical integrated device 300 comprises an optical functional element 100 and an optical circuit element 200. The optical functional element 100 is made of a compound semiconductor material such as InP, for example. The optical circuit element 200 is made of a semiconductor material such as Si, for example.

### Structure of Optical Functional Element of Optical Integrated Device According to Embodiment 1

The optical functional element 100 includes: an active layer 12 and a contact layer 13 formed above a compound semiconductor substrate 11; a protruding-shaped high-mesa section 16 that includes a part of the compound semiconductor substrate 11 and comprises at least the active layer 12 and the contact layer 13 from the side of the compound semiconductor substrate 11; a first electrode formed on the top surface of the high-mesa section 16; and planar-shaped terrace portions 14 that are provided along the high-mesa section 16 and are positioned at a predetermined height with respect to the active layer 12.

The active layer 12 has a refractive index higher than that of the material constituting the compound semiconductor substrate 11. The active layer 12 has a function that allows for the interaction of electricity and light, such as a multi-quantum well structure. The active layer 12 is formed above the compound semiconductor substrate 11 by epitaxial crystal growth.

The contact layer 13 is made of a material having a refractive index lower than that of the active layer 12. The contact layer 13 functions as a cladding to confine light into the active layer 12. The contact layer 13 also has a function of making electrical contact with electrodes formed on the surface thereof. The contact layer 13 is formed above the active layer 12 by epitaxial crystal growth.

The high-mesa section 16 is processed so that the width of the mesa is from sub-micron to several microns, and has a protruding shape with respect to the surface of the compound semiconductor substrate 11. The high-mesa section 16 includes the part of the compound semiconductor substrate 11 and is composed at least the active layer 12 and the contact layer 13 from the side of the compound semiconductor substrate 11. The high-mesa section 16 is formed by etching the active layer 12 and the contact layer 13, which are formed by epitaxial crystal growth above the compound semiconductor substrate 11, from the surface side of the contact layer 13 to provide a pair of mesa grooves 15. The width of each of the paired mesa grooves 15 is several microns.

The first electrode 17, which is made of a metal material excellent in conductivity such as gold (Au), titanium (Ti), or platinum (Pt), is formed on the top surface of the high-mesa section 16 so that a current can be injected into the contact layer 13 of the high-mesa section 16.

The terrace portions 14 are provided along the stripe-shaped high-mesa section 16 through the respective mesa grooves 15. The terrace portions 14 have a planar shape. The surfaces of the terrace portions 14 are the uppermost surface of the compound semiconductor substrate 11. That is, the height of the surface of the terrace portions 14 coincides with the height of the interface between the compound semiconductor substrate 11 and the active layer 12. The terrace portions 14 are formed by removing the active layer 12 above the compound semiconductor substrate 11 using selective etching or the like.

Since the terrace portions 14 are configured as described above, the surfaces of the terrace portions 14 are located at a predetermined height with respect to the active layer 12. In the case of the optical functional element 100 of the optical integrated device 300 according to Embodiment 1, the surfaces of the terrace portions 14 are located at a position that is lower by the thickness of the active layer 12 with respect to the surface of the active layer 12 on the side of the contact layer 13. When the thickness of the active layer 12 is dAL, the surfaces of the terrace portions 14 are located at a height of-dAL with reference to the surface of the active layer 12 on the side of the contact layer 13. In the optical functional element 100, the direction from the surface of the compound semiconductor substrate 11 toward the surface of the contact layer 13 is called the height direction. In other words, the direction toward minus in the y-axis direction is the height direction. Other embodiments are handled in the same manner.

The above is an overview of each configuration of the optical functional element 100.

### Structure of Optical Circuit Element in Optical Integrated Device According to Embodiment 1

The optical circuit element 200 including: a semiconductor substrate 21; a stacked structure substrate 40 including a lower cladding layer 22, a core layer 23 and an upper cladding layer 25, which are formed above the semiconductor substrate 21; a first recess 27a provided in the stacked structure substrate 40 and having one surface as an opening; second recesses 27b provided at a predetermined distance apart from the first recess 27a along both sides of the first recess 27a, with one end thereof in contact with the opening of the first recess 27a; and an optical waveguide section 24 provided in contact with one surface facing the opening of the first recess 27a and including the lower cladding layer 22, the core layer 23, and the upper cladding layer 25. The core layer originally means a layer that guides light, but a thin film layer formed at the same time as the core layer that guides light is referred to as the core layer 23 for convenience of explanation, even when it does not have a function of guiding light.

An example of the semiconductor substrate 21 is a Si substrate. The lower cladding layer 22 and the upper cladding layer 25 formed above the semiconductor substrate 21 have a structure like a so-called Buried Oxide layer (BOX layer) and are made of an insulating material such as silicon dioxide (SiO₂). The insulating material such as SiO₂ has a refractive index lower than that of the semiconductor substrate 21.

The core layer 23 is formed between the lower cladding layer 22 and the upper cladding layer 25 and is formed of, for example, a thin-film semiconductor layer. The thin-film semiconductor layer constituting the core layer 23 is made of a material having a refractive index higher than that of the lower cladding layer 22, for example, Si.

The first recess 27a is provided in the stacked structure substrate 40, and one of the four sides of the first recess 27a is an opening. The second recesses 27b are provided in the stacked structure substrate 40 at a predetermined distance apart from each other along two sides of the first recess 27a with one end in contact with the opening. As an example, the first recess 27a is provided with a shape in which one side is an opening, but it is not limited to a recess in which one side is an opening, and all four sides thereof may be formed as sides.

The optical waveguide section 24 includes the lower cladding layer 22, the core layer 23, and the upper cladding layer 25, and is etched on both sides to form a rectangular or protruding cross-sectional structure. The width of the optical waveguide is from sub-micron to several microns. One end of the optical waveguide section 24 is provided in contact with one surface facing the opening of the first recess 27a. The core layer 23 is sandwiched between the lower cladding layer 22 and the upper cladding layer 25, both of which have a refractive index lower than that of the core layer 23, thus the light that enters the core layer 23 from the end face propagates as guided light within the core layer 23.

Each protrusion portions 26 are formed between the first recess 27a and each second recesses 27b of the optical circuit element 200. The surface of the core layer 23 is exposed in the top 26a of each protrusion portion 26. That is, the outermost surface of the core layer 23 on the side that contacts the upper cladding layer 25 is exposed. Note that the upper cladding layer 25 is removed in an area that is at least as large as the optical functional element 100, and thus the outermost surface of the core layer 23 is exposed.

A second electrode 28 made of a metal material having excellent conductivity is formed in a part of the bottom of the first recess 27a.

The above is an overview of each configuration of the optical circuit element 200. In the optical circuit element 200, the direction from the surface of the semiconductor substrate 21 to the surface of the upper cladding layer 25 is called the height direction. In other words, the direction that goes towards the positive value on the y-axis is the height direction. Other embodiments are handled in the same manner.

### Mounting Configuration of Optical Functional Element and Optical Circuit Element in Optical Integrated Device According to Embodiment 1

The above-mentioned optical functional element 100 and optical circuit element 200 are integrated by flip-chip mounting to form the optical integrated device 300. The mounting configuration of the optical functional element 100 and the optical circuit element 200 will be described below.

The optical functional element 100 is bonded to the optical circuit element 200 in an upside-down orientation so that the compound semiconductor substrate 11 is on top. That is, the optical functional element 100 and the optical circuit element 200 are flip-chip mounted. When performing flip-chip mounting, the center of the high-mesa section 16 of the optical functional element 100 is aligned with the center of the first recess 27a of the optical circuit element 200.

Each terrace portion 14 of the optical functional element 100 is in contact with the top 26a of each protrusion portion 26 formed between the first recess 27a and each second recess 27b of the optical circuit element 200.

The top surface of the high-mesa section 16 is bonded to the bottom of the first recess 27a. Specifically, the first electrode 17 formed on the top surface of the high-mesa section 16 and the second electrode 28 formed on the bottom of the first recess 27a are electrically and mechanically bonded to each other by a bonding member 30. Examples of the bonding member 30 include solder and conductive adhesive.

As described above, when the optical functional element 100 and the optical circuit element 200 are integrated by flip-chip mounting, the active layer 12 of the high-mesa section 16 on the side of the optical functional element 100 and the core layer 23 of the optical waveguide section 24 on the side of the optical circuit element 200 are optically coupled. Details will be described later.

In FIGS. 3 and 4, in the case where the optical functional element 100 is a light-emitting device such as a semiconductor laser or a semiconductor optical amplifier (Semiconductor Optical Amplifier, SOA), the light propagation direction 80 is indicated by arrows. The arrows indicating the light propagation direction 80 in FIGS. 3 and 4 are inverted when the optical functional element 100 is a light-receiving device, such as a photodiode (PD). However, since the light-receiving device can be handled in the same manner as a light-emitting device in Embodiment 1, the two are not distinguished here. FIG. 6 schematically shows the spread 81 of the optical mode propagating through the high-mesa section 16 of the optical functional element 100.

### Method for Manufacturing Optical Functional Element in Optical Integrated Device According to Embodiment 1

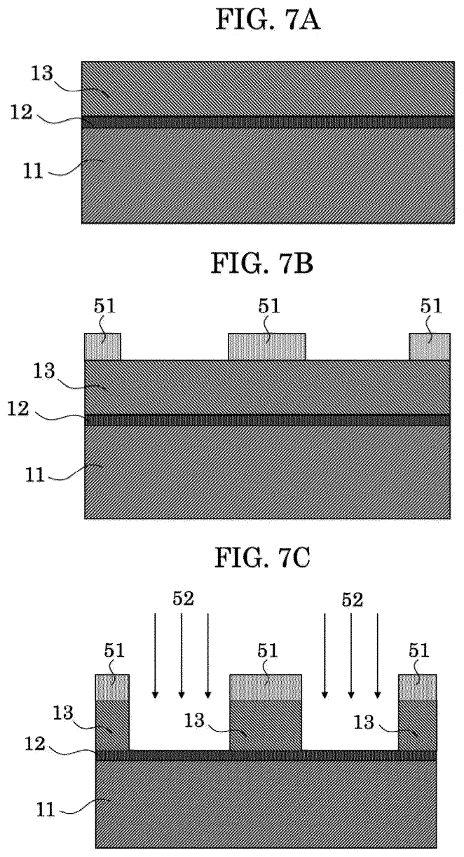

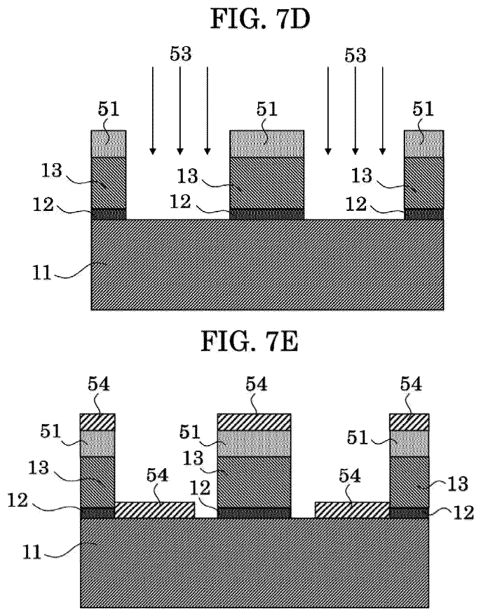

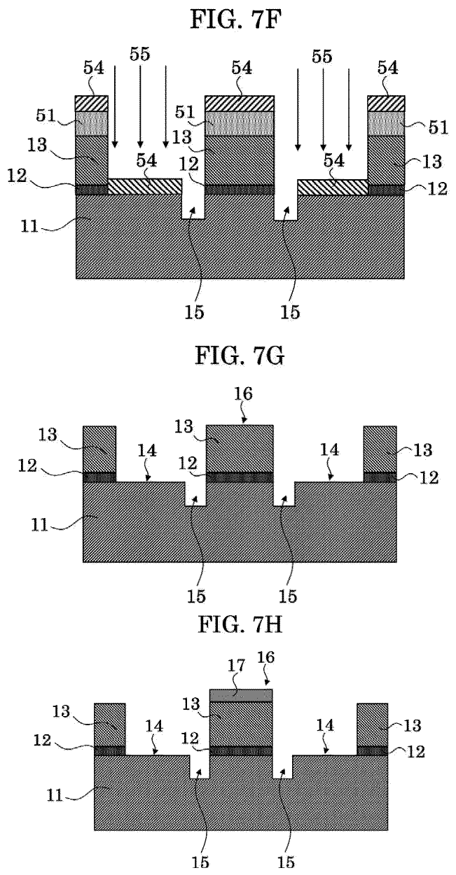

A method for manufacturing an optical functional element in the optical integrated device 300 according to Embodiment 1 will be described below with reference to FIGS. 7A to 7H.

First, as shown in FIG. 7A, the active layer 12 includes a multi-quantum well structure (MQW) made of indium gallium arsenide phosphide (InGaAsP) having a composition ratio corresponding to a photoluminescence peak wavelength of 1.2 μm or more, or made of aluminum gallium indium arsenide (AlGaInAs) having a composition ratio corresponding to a similar peak wavelength, and the contact layer 13 are sequentially epitaxially grown above the compound semiconductor substrate 11 made of, for example, InP. Examples of epitaxial crystal growth methods include metal organic vapor deposition (MOCVD) and molecular beam epitaxy (MBE). The contact layer 13 is made of, for example, n-type or p-type doped InP.

After epitaxial crystal growth, as shown in FIG. 7B, a mask 51 made of an insulating film such as SiO₂ is formed using photolithography and etching techniques to protect the high-mesa section 16 and the non-terrace portion, that is, the portions other than the terrace portions 14.

As shown in FIG. 7C, the part of the contact layer 13 that is not covered by the mask 51 is selectively removed by dry etching 52 having high vertical property. After etching, the outermost surface of the active layer 12 is exposed in the portion not covered by the mask 51.

Next, as shown in FIG. 7D, the part of the active layer 12 that is not covered by the mask 51 is selectively etched and removed by wet etching using, for example, a mixed solution 53 of tartaric acid and hydrogen peroxide as an etchant. The outermost surface of the compound semiconductor substrate 11 is exposed in the portion not covered by the mask 51.

Next, as shown in FIG. 7E, a mask 54 made of an insulating film such as SiO₂ is formed to cover the part covered by the mask 51 and the terrace portions 14. The mask 54 has an opening in the area where the mesa grooves 15 are to be formed.

After the mask 54 is formed, as shown in FIG. 7F, the part of the compound semiconductor substrate 11 that is not covered by the mask 54 is removed using dry etching 55 having high vertical property again to form the mesa grooves 15, thereby completing the protruding-shaped high-mesa section 16.

Next, as shown in FIG. 7G, the mask 51 and the mask 54 are removed by dry etching or wet etching.

Finally, as shown in FIG. 7H, the first electrode 17 is formed on the top surface of the high-mesa section 16. Examples of metal materials constituting the first electrode 17 include Au, Ti, Pt, and the like. The first electrode 17 is formed by, for example, electron beam evaporation.

Through the above-mentioned manufacturing processes, the optical functional element 100 is completed.

### Method for Manufacturing Optical Circuit Element in Optical Integrated Device According to Embodiment 1

The optical circuit element 200 is manufactured by a known manufacturing method applying silicon processing technology. Consequently, the details of the manufacturing method of the optical circuit element 200 are omitted.

### Method for Manufacturing Optical Integrated Device According to Embodiment 1

The compound semiconductor substrate 11 of the optical functional element 100 is arranged in an upside-down orientation so that the compound semiconductor substrate 11 is on the upper side of the optical circuit element 200, and the center of the high-mesa section 16 of the optical functional element 100 is aligned with the center of the first recess 27a of the optical circuit element 200, and then the optical functional element 100 and the optical circuit element 200 are flip-chip mounted.

In the optical functional element 100 and the optical circuit element 200, each terrace portion 14 of the optical functional element 100 contacts the top 26a of each protrusion portion 26 formed between the first recess 27a and each second recess 27b of the optical circuit element 200. The first electrode 17 formed on the top surface of the high-mesa section 16 and the second electrode 28 formed on the bottom of the first recess 27a are electrically and mechanically bonded to each other by the bonding member 30.

Through the above-mentioned manufacturing processes, the optical integrated device 300 in which the optical functional element 100 and the optical circuit element 200 are flip-chip mounted is completed.

Through the above-mentioned manufacturing processes for the optical functional element 100, the relative positional misalignment in the height direction between the optical functional element 100 and the optical circuit element 200 can be precisely controlled without using so-called etching stop layers by utilizing selective etching of the constituent material of the active layer 12 and the constituent material other than the active layer 12.

In contrast, in the case where the above-described height control method is used, the positions of the terrace portions 14 are limited to the interface between the active layer 12 and the compound semiconductor substrate 11. Therefore, in Embodiment 1, in the optical circuit element 200, the upper cladding layer 25 of the top 26a of each protrusion portion 26, which is the region on which the optical functional element 100 is to be mounted, is selectively removed, so that the distance in the height direction between the active layer 12 of the high-mesa section 16 of the optical functional element 100 and the core layer 23 of the optical waveguide section 24 of the optical circuit element 200 substantially matches each other with sub-micron accuracy.

### Operation and Features of Optical Integrated Device According to Embodiment 1

The operation and features of the optical integrated device 300 according to Embodiment 1 will be described below.

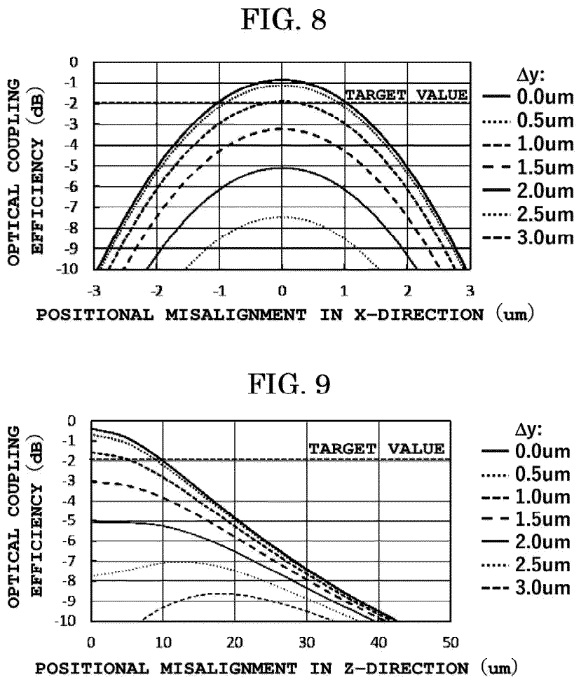

FIG. 8 shows the results of calculation of the relationship between the relative positional misalignment in the x-direction and y-direction and the optical coupling efficiency in the case where the optical functional element 100 emitting the light having a 1/e² half-angle far field pattern (FFP) of 20 degrees and a wavelength of 1.55 μm from the active layer 12 of the high-mesa section 16, and the optical circuit element 200 emitting the light having a 1/e² half-angle FFP of 15 degrees from the core layer 23 of the optical waveguide section 24 are opposed to each other at a distance of 5 μm in the z-direction shown in FIG. 1.

Assuming that the target value of the coupling efficiency is −2 dB (=63%), in the case where the y-direction misalignment is 1.0 μm, the allowable x-direction misalignment to achieve the target value is about ±0.3 μm or less, which is a very strict numerical value.

In contrast, in the case where the y-direction misalignment can be precisely controlled to within 0.5 μm, the allowable x-direction misalignment to achieve the target value is about ±1.0 μm or less, which is a reasonable value even taking manufacturing variation into consideration.

FIG. 9 shows the results of calculation of the relationship between the relative positional misalignment in the y-direction and z-direction and the optical coupling efficiency in the case where the optical functional element 100 emitting the light having a 1/e² half-angle FFP of 20 degrees from the active layer 12 of the high-mesa section 16, and the optical circuit element 200 emitting the light having a 1/e² half-angle FFP of 15 degrees from the core layer 23 of the optical waveguide section 24 are opposed to each other at a distance of 0 μm in the z-direction shown in FIG. 1.

As in the case of FIG. 8, in the case where the y-direction misalignment is 1.0 μm, the allowable x-direction misalignment to achieve the target value is about 6 μm or less, which is a very strict numerical value. In contrast, in the case where the y-direction misalignment can be precisely controlled to within 0.5 μm, the allowable z-direction misalignment to achieve the target value is 10 μm or less, which is a reasonable value even taking manufacturing variation into consideration.

As shown in FIG. 8, in the case where the y-direction misalignment is 2.5 μm or more, the maximum value of the optical coupling efficiency is other than z=0 μm. This indicates that in the case where the relative vertical misalignment with respect to light propagation becomes too large, it is preferable to place the optical functional element 100 at a position where the light is diffused slightly further away than in the case where the optical axis misalignment is zero, in order to guide more light power into the core layer 23 of the optical waveguide section 24 of the optical circuit element 200.

The calculation results mentioned above show that in order to achieve high optical coupling efficiency between the optical functional element 100 and the optical circuit element 200, the relative positional misalignment in the height direction between the optical functional element 100 and the optical circuit element 200 is 1 μm or less, more preferably about 0.5 μm, and the relative positional misalignment in the optical axis direction is preferably 6 μm or less.

In the optical integrated device 300 according to Embodiment 1, since each terrace portion 14 located at a height just below the active layer 12 of the optical functional element 100 and the top 26a of each protrusion portion 26 located at a height just above the core layer 23 of the optical waveguide section 24 of the optical circuit element 200 is in contact with each other by flip-chip mounting, the relative positional misalignment between each terrace portion 14 and each top 26a in the height direction is not larger than the relative positional misalignment in the height direction between the active layer 12 of the optical functional element 100 and the core layer 23 of the optical waveguide section 24 of the optical circuit element 200. Since the relative positional misalignment in the height direction between the optical functional element 100 and the optical circuit element 200 is generally about 0.5 μm, the target value of optical coupling efficiency can be ensured by adopting the optical integrated device 300 according to Embodiment 1.

Meanwhile, with regard to relative positional misalignment in the axial direction, that is, the y-direction, a requirement of relative positional misalignment of 6 μm or less can be easily achieved by forming alignment marks on the optical functional element 100 and the optical circuit element 200, for example in the shape of a cross, and then performing alignment while observing the relative positions of each using a camera or similar device.

Note that the shape, material, and positional relationship of the optical integrated device 300 need not be limited to the configuration of Embodiment 1. For example, the optical functional element 100 may be a light-receiving device such as a photodiode (PD) instead of a light-emitting device such as a semiconductor laser or SOA. In the case of the light-receiving device, the same principle can be applied by reversing the direction of light input and output.

Moreover, the optical integrated device may be such that both the light incident from the optical circuit element 200 to the optical functional element 100 and the light emitted from the optical functional element 100 to the optical circuit element 200 are mixed, such as MZ (Mach-Zehnder) modulator or EA (Electro-Absorption) modulator.

In addition to InP, the compound semiconductor material may be a GaAs-based material, a GaN-based material, or a mixed crystal system. The optical circuit element 200 has been described as an example of a structure including the lower cladding layer 22 made of SiO₂, the core layer 23 made of a thin Si film, and the upper cladding layer 25 made of SiO₂ above the Si substrate. Alternatively, a silicon nitride film (SiN) or a silicon oxynitride film (SiON) may be used to form the core layer 23, or a non-silicon material such as lithium niobate (LiNbO3) may be used. When SiN or SiON is used as the core layer 23, there is a disadvantage that the device size becomes larger because the refractive index thereof is lower than that of Si, whereas there is an advantage that a low-loss optical integrated device can be achieved because the optical loss of propagating light is smaller than that of Si.

Using SiN or SiON as the core layer 23 has the advantage that the mode distribution of the propagating light is wider than that of the core layer 23 made of Si thin film, thus relaxing the tolerance of the optical coupling efficiency to the relative positional misalignment between the optical functional element 100 and the optical circuit element 200.

In the case where LiNbO₃ is used as the core layer 23, since LiNbO₃ is a ferroelectric material having a high E/O coefficient, the refractive index can be changed by applying an electric field to LiNbO₃, thus making it possible to give functions such as MZ modulators to the optical circuit element 200. Moreover, utilizing the change in the refractive index of LiNbO₃ makes it possible to adjust the optical mode distribution of the propagating light, and to actively compensate for the relative positional misalignment between the optical functional element 100 and the optical circuit element 200.

### Effects of Embodiment 1

As described above, in the optical integrated device and the method for manufacturing the optical integrated device according to Embodiment 1, the surfaces of the terrace portions of the optical functional element are the uppermost surface of the compound semiconductor substrate, thereby the relative positional misalignment between the optical functional element and the optical circuit element in the height direction can be precisely controlled, thus providing an effect that the optical integrated device and the method for manufacturing the optical integrated device with high optical coupling efficiency can be obtained.

### Modification of Embodiment 1

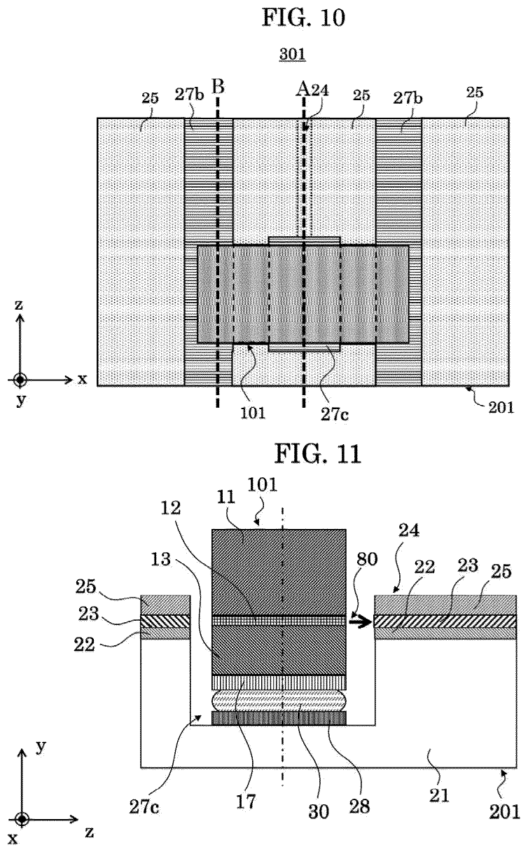

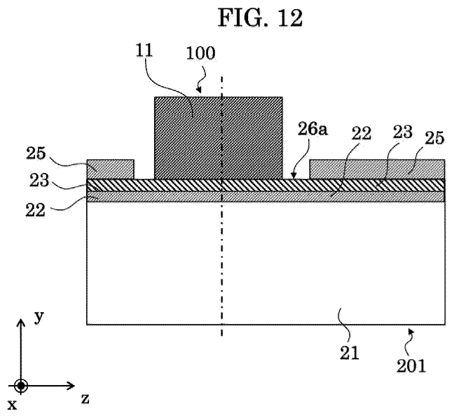

FIG. 10 is a top view showing the structure of an optical integrated device 301 according to Modification of Embodiment 1. FIG. 11 is a cross-sectional view along line A in FIG. 10 for the optical integrated device 301 according to Modification of Embodiment 1. FIG. 12 is a cross-sectional view along line B in FIG. 10 for the optical integrated device 301 according to Modification of Embodiment 1. In FIGS. 10 to 12, the xyz axis directions are shown for convenience of explanation.

The optical integrated device 301 according to Modification of Embodiment 1 differs from the optical integrated device 300 according to Embodiment 1 in that one of the four sides of the first recess 27 a provided in the optical circuit element 200 of the optical integrated device 300 has an opening, whereas in the optical integrated device 301 according to Modification of Embodiment 1, no opening is provided in any of the four sides of the first recess 27c provided in the optical circuit element 201. That is, in the configuration in which the optical functional element 101 and the optical circuit element 201 are flip-chip mounted, the high-mesa section 16 of the optical functional element 101 enters into the first recess 27c, and the periphery thereof is surrounded by the sides of the first recess 27c.

In the optical integrated device 301 according to Modification of Embodiment 1, in addition to the propagation direction 80 of the light emitted from the high-mesa section 16 of the optical functional element 101 toward the optical waveguide section 24 of the optical circuit element 201, the light emitted from the other end face of the high-mesa section 16 is also waveguided into the optical circuit element 201 so that the optical integrated device 301 can achieve even higher functionality.

### Effects of Modification of Embodiment 1

As described above, in the optical integrated device according to Modification of Embodiment 1, the surfaces of the terrace portions of the optical functional element are the uppermost surface of the compound semiconductor substrate, in addition to the effect of precisely controlling the relative positional misalignment between the optical functional element and the optical circuit element in the height direction, thereby the light emitted from the other end face of the high-mesa section of the optical functional element can be also utilized, thus providing an effect of achieving even higher functionality of the optical integrated device.

### Embodiment 2

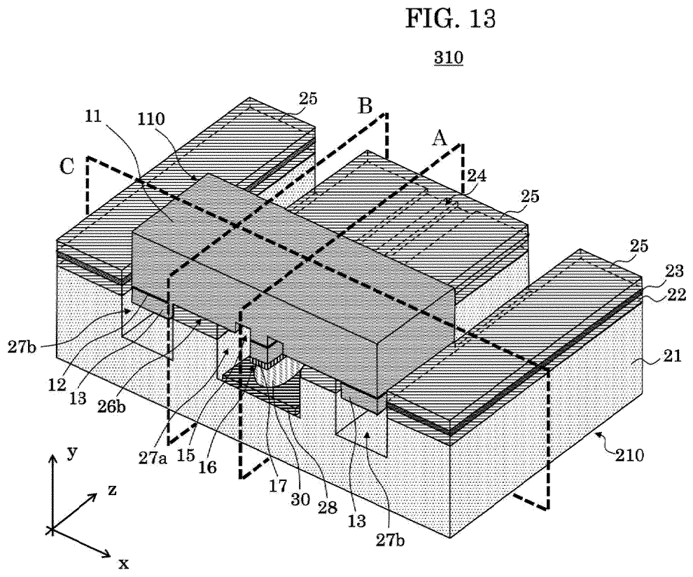

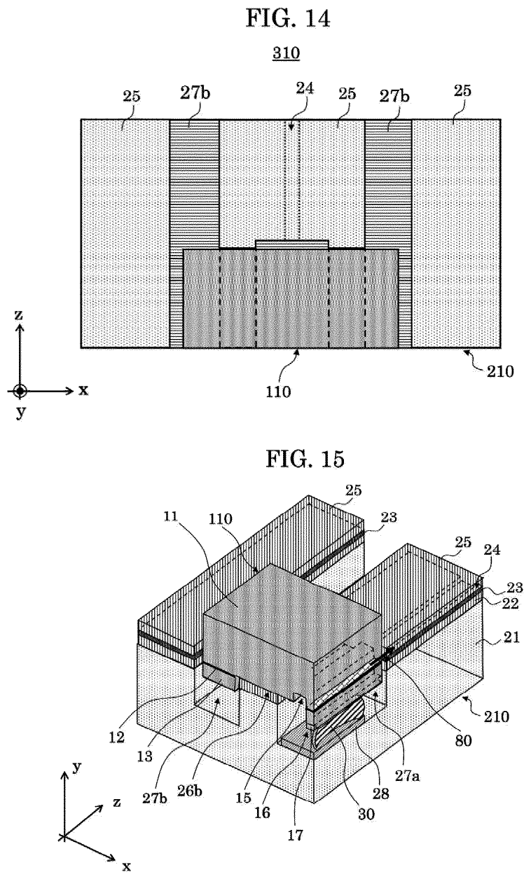

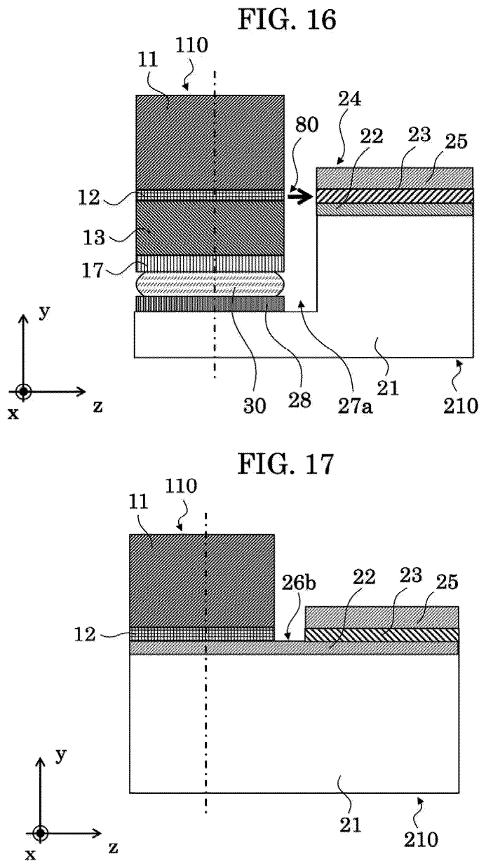

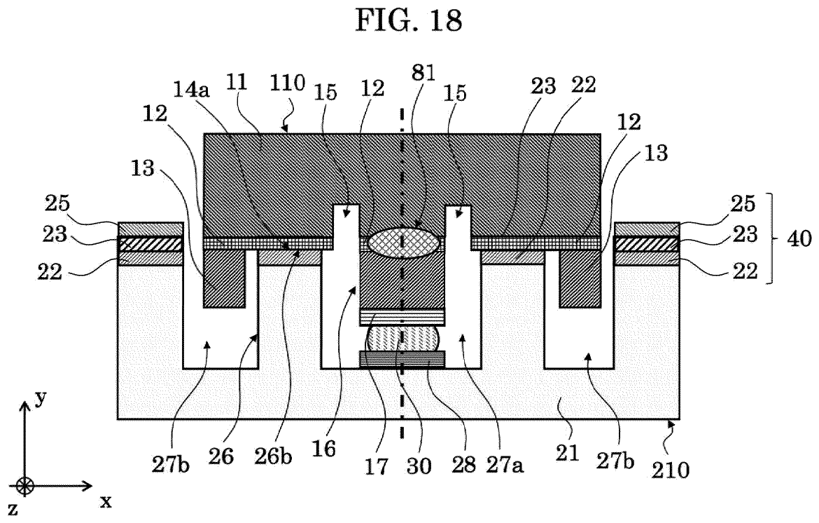

FIG. 13 is an overview diagram showing a structure of an optical integrated device 310 according to Embodiment 2. FIG. 14 is a top view showing the structure of the optical integrated device 300 according to Embodiment 1. FIG. 15 is an overview diagram showing the optical integrated device 310 according to Embodiment 2 as viewed from a cross section along line A in FIG. 13. FIG. 16 is a cross-sectional view along line A in FIG. 13 for the optical integrated device 310 according to Embodiment 2. FIG. 17 is a cross-sectional view along line B in FIG. 13 for the optical integrated device 310 according to Embodiment 2. FIG. 18 is a cross-sectional view along line C in FIG. 13 for the optical integrated device 310 according to Embodiment 2. In FIGS. 13 to 18, the xyz axis directions are shown for convenience of explanation. FIG. 18 schematically shows the spread 81 of the optical mode propagating through a high-mesa section 16 of an optical functional element 110.

### Configuration of Optical Integrated Device According to Embodiment 2

The optical integrated device 310 comprises an optical functional element 110 and an optical circuit element 210. The optical functional element 110 is made of a compound semiconductor material such as InP, for example. The optical circuit element 210 is made of a semiconductor material such as Si, for example.

### Structure of Optical Functional Element of Optical Integrated Device According to Embodiment 2

The optical functional element 110 includes: an active layer 12 and a contact layer 13 formed above a compound semiconductor substrate 11; a protruding-shaped high-mesa section 16 that includes a part of the compound semiconductor substrate 11 and comprises at least the active layer 12 and the contact layer 13 from the side of the compound semiconductor substrate 11; a first electrode 17 formed on the top surface of the high-mesa section 16; and planar-shaped terrace portions 14a that are provided along the high-mesa section 16 and are positioned at a predetermined height with respect to the active layer 12. In the following description, only the parts structurally different from the optical functional element 100 of the optical integrated device 300 according to Embodiment 1 will be described.

The terrace portions 14a are provided along the stripe-shaped high-mesa section 16 through the respective mesa grooves 15. The terrace portions 14a have a planar shape. The surfaces of the terrace portions 14a are the uppermost surface of the active layer 12. That is, the height of the surface of the terrace portions 14a coincides with the height of the interface between the active layer 12 and the contact layer 13. The terrace portions 14a are formed by removing the contact layer 13 above the active layer 12 using selective etching or the like.

Since the terrace portions 14a are configured as described above, the surfaces of the terrace portions 14a are located at a predetermined height with respect to the active layer 12. In the case of the optical functional element 110 of the optical integrated device 310 according to Embodiment 2, the surfaces of the terrace portions 14a are located at the same height as the surface of the active layer 12 on the side of the contact layer 13. That is, the surfaces of the terrace portions 14 are located at a height of zero with reference to the surface of the active layer 12 on the side of the contact layer 13.

The above is an overview of each configuration of the optical functional element 110.

### Configuration of Optical Circuit Element in Optical Integrated Device According to Embodiment 2

The optical circuit element 210 according to Embodiment 2 has basically the same configuration as the optical circuit element 200 according to Embodiment 1, but some configurations are different. Consequently, only the different configurations will be described below.

The lower cladding layer 22 is exposed in the top 26b of each protrusion portion 26 formed between the first recess 27a and each second recess 27b of the optical circuit element 210. That is, the outermost surface of the lower cladding layer 22 on the side that contacts the core layer 23 is exposed. Note that the upper cladding layer 25 and the core layer 23 are removed in an area that is at least as large as the optical functional element 110, and thus the outermost surface of the lower cladding layer 22 is exposed. In this respect, the optical circuit element 210 differs from the optical circuit element 200 of Embodiment 1, in which the core layer 23 is exposed at the top 26b of each protrusion portion 26.

The above are the distinctive features of the configuration of the optical circuit element 210.

### Mounting Configuration of Optical Functional Element and Optical Circuit Element in Optical Integrated Device According to Embodiment 2

The above-mentioned optical functional element 110 and optical circuit element 210 are integrated by flip-chip mounting to form the optical integrated device 310. The mounting configuration of the optical functional element 110 and the optical circuit element 210 will be described below.

The optical functional element 110 is bonded to the optical circuit element 210 in an upside-down orientation so that the compound semiconductor substrate 11 is on top. That is, the optical functional element 110 and the optical circuit element 210 are flip-chip mounted. When performing flip-chip mounting, the center of the high-mesa section 16 of the optical functional element 110 is aligned with the center of the first recess 27a of the optical circuit element 210.

Each terrace portion 14a of the optical functional element 110 is in contact with the top 26b of each protrusion portion 26 formed between the first recess 27a and each second recess 27b of the optical circuit element 210.

The top surface of the high-mesa section 16 is bonded to the bottom of the first recess 27a. Specifically, the first electrode 17 formed on the top surface of the high-mesa section 16 and the second electrode 28 formed on the bottom of the first recess 27a are electrically and mechanically bonded to each other by a bonding member 30. Examples of the bonding member 30 include solder and conductive adhesive.

As described above, when the optical functional element 110 and the optical circuit element 210 are integrated by flip-chip mounting, the active layer 12 of the high-mesa section 16 on the side of the optical functional element 110 and the core layer 23 of the optical waveguide section 24 on the side of the optical circuit element 210 are optically coupled.

### Method for Manufacturing Optical Functional Element in Optical Integrated Device According to Embodiment 2

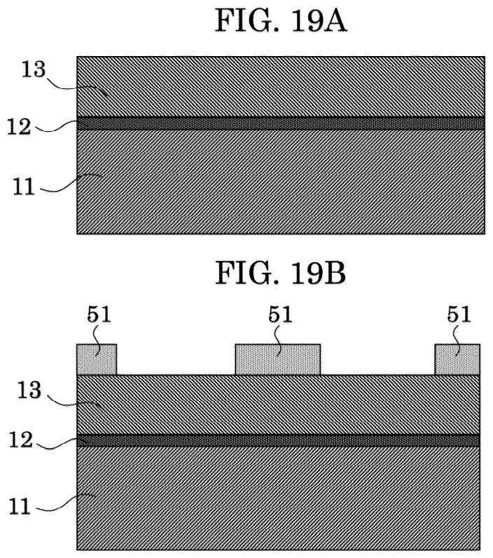

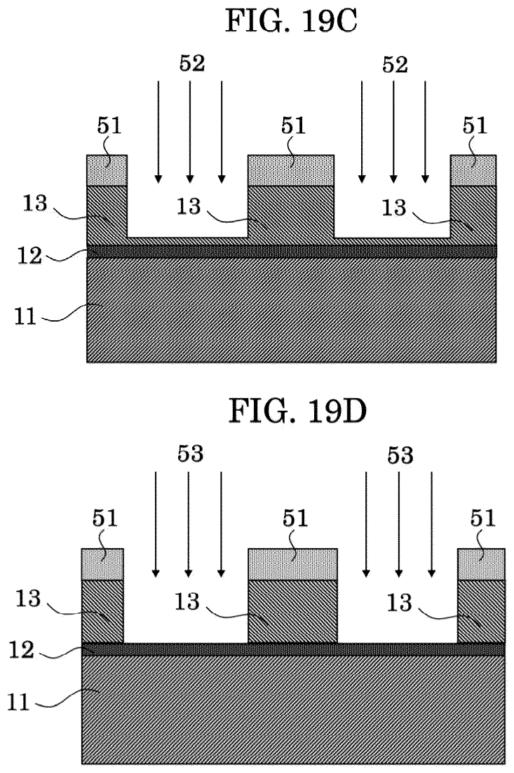

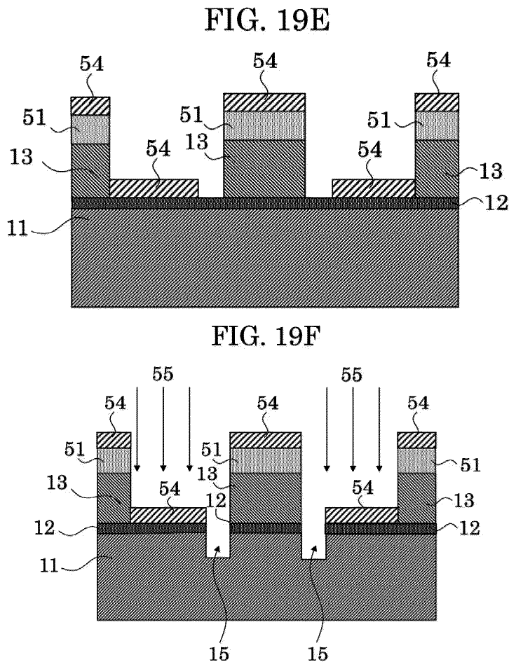

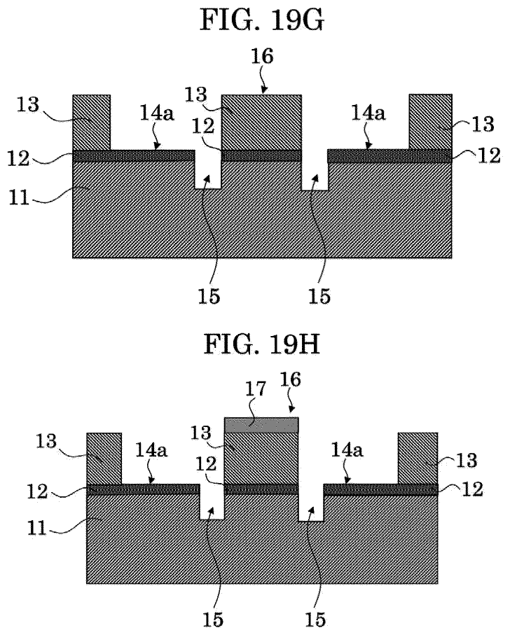

A method for manufacturing an optical functional element 110 in the optical integrated device 310 according to Embodiment 2 will be described below with reference to FIGS. 19A to 19H.

First, as shown in FIG. 19A, the active layer 12 including a multi-quantum well structure made of InGaAsP having a composition ratio corresponding to a photoluminescence peak wavelength of 1.2 μm or more, or made of AlGaInAs having a composition ratio corresponding to a similar peak wavelength, and the contact layer 13 are sequentially epitaxially grown above the compound semiconductor substrate 11 made of, for example, InP. Examples of epitaxial crystal growth methods include MOCVD and MBE. The contact layer 13 is made of, for example, n-type or p-type doped InP.

After epitaxial crystal growth, as shown in FIG. 19B, a mask 51 made of an insulating film such as SiO₂ is formed using photolithography and etching techniques to protect the high-mesa section 16 and the non-terrace portion, that is, the portions other than the terrace portions 14a.

As shown in FIG. 19 C, the part of the contact layer 13 that is not covered by the mask 51 is removed by using dry etching 52 having high vertical property, leaving a small thickness.

Next, as shown in FIG. 19D, the part of the contact layer 13 that is not covered by the mask 51 is selectively etched and removed by wet etching using, for example, a mixed solution 53 of hydrochloric acid and phosphoric acid as an etchant. After etching, the outermost surface of the active layer 12 is exposed in the portion not covered by the mask 51.

Next, as shown in FIG. 19E, a mask 54 made of an insulating film such as SiO₂ is formed so as to cover the part covered by the mask 51 and the terrace portions 14a. The mask 54 has an opening in the area where the mesa grooves 15 are to be formed.

After the mask 54 is formed, as shown in FIG. 19F, the part of the compound semiconductor substrate 11 and the active layer 12 that are not covered by the mask 54 are removed using dry etching 55 having high vertical property again to form the mesa grooves 15, thereby completing the protruding-shaped high-mesa section 16.

Next, as shown in FIG. 19G, the mask 51 and the mask 54 are removed by dry etching or wet etching.

Finally, as shown in FIG. 19H, the first electrode 17 is formed on the top surface of the high-mesa section 16. Examples of metal materials constituting the first electrode 17 include Au, Ti, Pt, and the like. The first electrode 17 is formed by, for example, electron beam evaporation.

Through the above-mentioned manufacturing processes, the optical functional element 110 is completed.

### Method for Manufacturing Optical Integrated Device According to Embodiment 2

The compound semiconductor substrate 11 of the optical functional element 110 is arranged in an upside-down orientation so that the compound semiconductor substrate 11 is on the upper side of the optical circuit element 210, and the center of the high-mesa section 16 of the optical functional element 110 is aligned with the center of the first recess 27a of the optical circuit element 210, and then the optical functional element 110 and the optical circuit element 210 are flip-chip mounted.

In the optical functional element 110 and the optical circuit element 210, each terrace portion 14a of the optical functional element 110 contacts the top 26a of each protrusion portion 26 formed between the first recess 27a and each second recess 27b of the optical circuit element 210. The first electrode 17 formed on the top surface of the high-mesa section 16 and the second electrode 28 formed on the bottom of the first recess 27a are electrically and mechanically bonded to each other by the bonding member 30.

Through the above-mentioned manufacturing processes, the optical integrated device 310 in which the optical functional element 110 and the optical circuit element 210 are flip-chip mounted is completed.

Through the above-mentioned manufacturing processes for the optical functional element 110, the relative positional misalignment in the height direction between the optical functional element 110 and the optical circuit element 210 can be precisely controlled without using so-called etching stop layers by utilizing selective etching of the constituent material of the active layer 12 and the constituent material other than the active layer 12.

In contrast, in the case where the above-described height control method is used, the positions of the terrace portions 14a are limited to the interface between the active layer 12 and the contact layer 13. Therefore, in Embodiment 2, in the optical circuit element 210, the upper cladding layer 25 and the core layer 23 of the top 26b of each protrusion portion 26, which is the region on which the optical functional element 110 is to be mounted, are selectively removed, so that the distance in the height direction between the active layer 12 of the high-mesa section 16 of the optical functional element 110 and the core layer 23 of the optical waveguide section 24 of the optical circuit element 210 substantially matches each other with sub-micron accuracy.

### Operation and Features of Optical Integrated Device According to Embodiment 2

By applying such a structure as the optical functional element 110, since each terrace portion 14a located immediately above the active layer 12 of the optical functional element 110 and the top 26b of each protrusion portion 26 located immediately below the optical waveguide section 24 of the optical circuit element 210 are in contact with each other by flip-chip mounting, the relative positional misalignment in the height direction between the optical functional element 110 and the optical circuit element 210 is not larger than the relative positional misalignment in the height direction between the active layer 12 of the optical functional element 110 and the core layer 23 of the optical waveguide section 24 of the optical circuit element 210.

Since the relative positional misalignment in the height direction between the optical functional element 110 and the optical circuit element 210 is generally about 0.5 μm, the relative positional misalignment in the height direction between the optical functional element 110 and the optical circuit element 210 is reduced to 1 μm or less, which satisfies the requirement of about 0.5 μm, thus ensuring the achievement of high optical coupling efficiency.

The optical integrated device 310 according to Embodiment 2, as with Embodiment 1, is able to achieve high mounting accuracy in the height direction of the optical functional element 110 and the optical circuit element 210 without using an etching stop layer, by devising the device structure and manufacturing method, thus providing an effect of avoiding the problem of optical loss occurring during light propagation and optical coupling between different optical elements due to deformation of the propagating light mode caused by different refractive index regions, which is a problem when an etching stop layer is provided.

### Effects of Embodiment 2

As described above, in the optical integrated device and the method for manufacturing the optical integrated device according to Embodiment 2, the surfaces of the terrace portions of the optical functional element are the uppermost surface of the active layer, thereby the relative positional misalignment between the optical functional element and the optical circuit element in the height direction can be precisely controlled, thus providing an effect that the optical integrated device and the method for manufacturing the optical integrated device with high optical coupling efficiency can be obtained.

### Modification of Embodiment 2

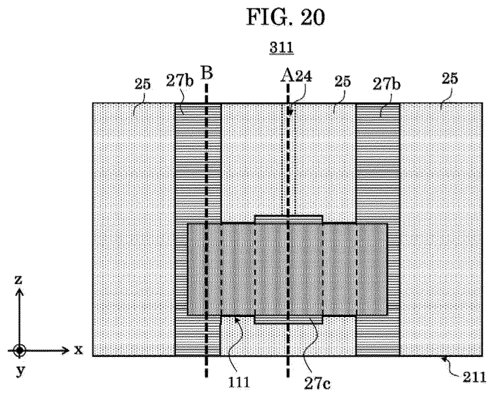

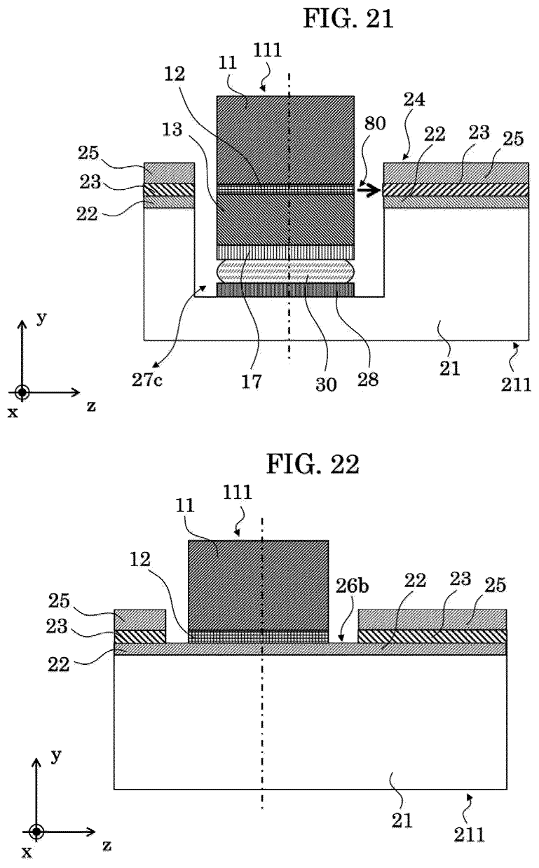

FIG. 20 is a top view showing the structure of an optical integrated device 311 according to Modification of Embodiment 2. FIG. 21 is a cross-sectional view along line A in FIG. 20 for the optical integrated device 311 according to Modification of Embodiment 2. FIG. 22 is a cross-sectional view along line B in FIG. 20 for the optical integrated device 311 according to Modification of Embodiment 2. In FIGS. 20 to 22, the xyz axis directions are shown for convenience of explanation.

The optical integrated device 311 according to Modification of Embodiment 2 differs from the optical integrated device 310 according to Embodiment 2 in that one of the four sides of the first recess 27 a provided in the optical circuit element 210 of the optical integrated device 310 has an opening, whereas in the optical integrated device 311 according to Modification of Embodiment 2, no opening is provided in any of the four sides of the first recess 27c provided in the optical circuit element 211. That is, in the configuration in which the optical functional element 111 and the optical circuit element 211 are flip-chip mounted, the high-mesa section 16 of the optical functional element 111 enters into the first recess 27c, and the periphery thereof is surrounded by the sides of the first recess 27c.

In the optical integrated device 311 according to Modification of Embodiment 2, in addition to the propagation direction 80 of the light emitted from the high-mesa section 16 of the optical functional element 111 toward the optical waveguide section 24 of the optical circuit element 211, the light emitted from the other end face of the high-mesa section 16 is also waveguided into the optical circuit element 211 so that the optical integrated device 311 can achieve even higher functionality.

### Effects of Modification of Embodiment 2

As described above, in the optical integrated device according to Modification of Embodiment 2, the surfaces of the terrace portions of the optical functional element are the uppermost surface of the active layer, thereby the relative positional misalignment between the optical functional element and the optical circuit element in the height direction can be precisely controlled, thus providing an effect of obtaining an optical integrated device with high optical coupling efficiency. Furthermore, the light emitted from the other end face of the high-mesa section of the optical functional element can be also utilized, thus providing an effect of achieving even higher functionality of the optical integrated device.

### Embodiment 3

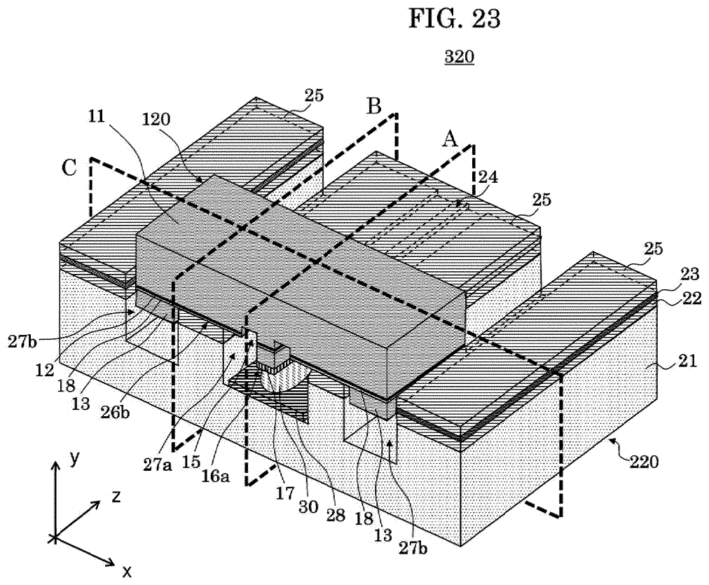

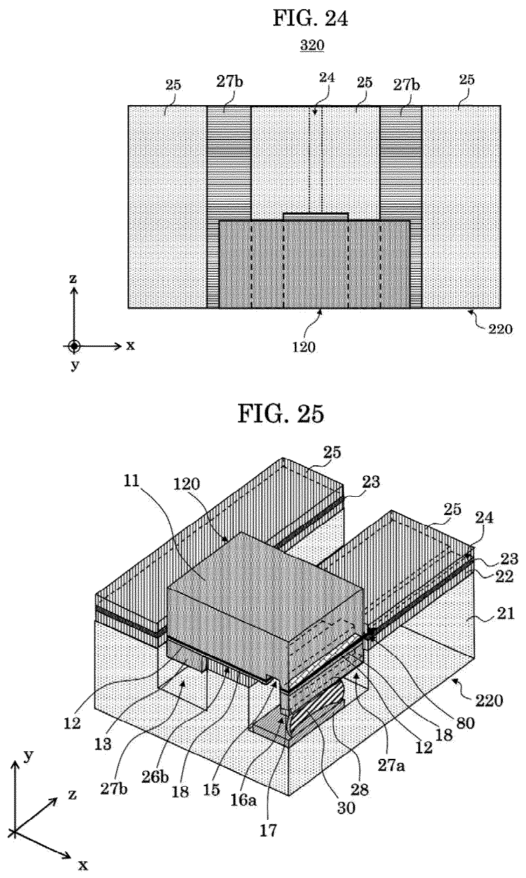

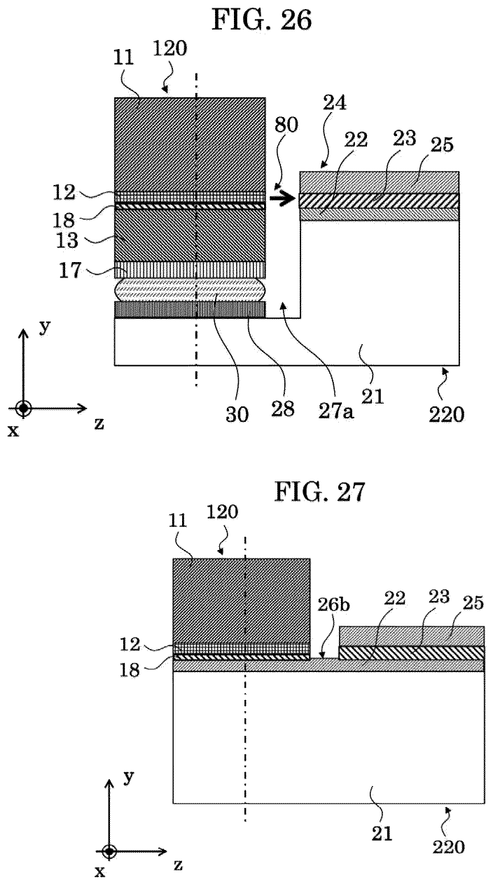

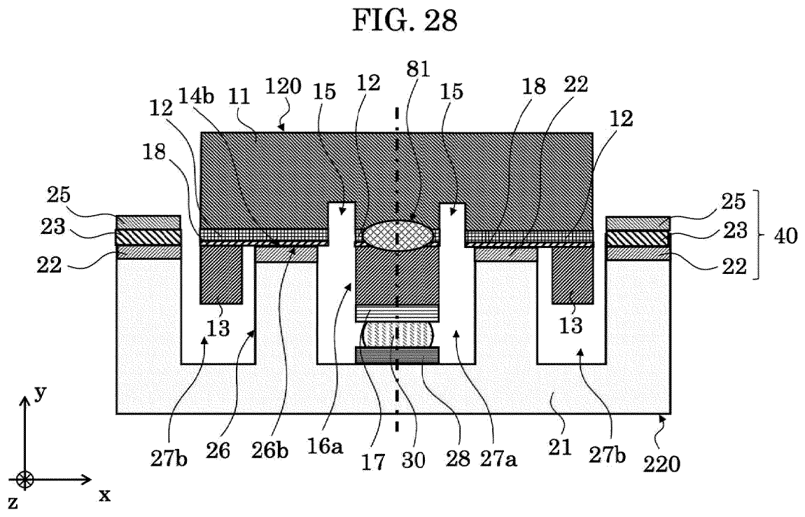

FIG. 23 is an overview diagram showing a structure of an optical integrated device 320 according to Embodiment 3. FIG. 24 is a top view showing the structure of the optical integrated device 320 according to Embodiment 3. FIG. 25 is an overview diagram showing the optical integrated device 320 according to Embodiment 3 as viewed from a cross section along line A in FIG. 23. FIG. 26 is a cross-sectional view along line A in FIG. 23 for the optical integrated device 320 according to Embodiment 3. FIG. 27 is a cross-sectional view along line B in FIG. 23 for the optical integrated device 320 according to Embodiment 3. FIG. 28 is a cross-sectional view along line C in FIG. 23 for the optical integrated device 320 according to Embodiment 3. In FIGS. 23 to 28, the xyz axis directions are shown for convenience of explanation. FIG. 28 schematically shows the spread 81 of the optical mode propagating through a high-mesa section 16 of an optical functional element 120.

### Configuration of Optical Integrated Device According to Embodiment 3

The optical integrated device 320 comprises an optical functional element 120 and an optical circuit element 120. The optical functional element 120 is made of a compound semiconductor material such as InP, for example. The optical circuit element 220 is made of a semiconductor material such as Si, for example.

### Structure of Optical Functional Element of Optical Integrated Device According to Embodiment 3

The optical functional element 120 includes: an active layer 12, an etching stop layer 18, and a contact layer 13 formed above a compound semiconductor substrate 11; a protruding-shaped high-mesa section 16a that includes a part of the compound semiconductor substrate 11 and comprises at least the active layer 12, the etching stop layer 18, and the contact layer 13 from the side of the compound semiconductor substrate 11; a first electrode 17 formed on the top surface of the high-mesa section 16a; and planar-shaped terrace portions 14b that are provided along the high-mesa section 16a and are positioned at a predetermined height with respect to the active layer 12.

The etching stop layer 18 has a property of exhibiting a reactivity different from that of the contact layer 13 described later in a specific etching process. The characteristic of the optical functional element 120 of Embodiment 3 is that the etching stop layer 18 is provided between the active layer 12 and the contact layer 13 of the high-mesa section 16a. In the following description, only the parts structurally different from the optical functional element 100 of the optical integrated device 300 according to Embodiment 1 will be described.

The terrace portions 14b are provided along the stripe-shaped high-mesa section 16a through the respective mesa grooves 15. The terrace portions 14b have a planar shape. The surfaces of the terrace portions 14b are the uppermost surface of the etching stop layer 18. That is, the height of the surface of the terrace portions 14b coincides with the height of the interface between the etching stop layer 18 and the contact layer 13. The terrace portions 14b are formed by removing the contact layer 13 above the etching stop layer 18 using selective etching or the like.

Since the terrace portions 14b are configured as described above, the surfaces of the terrace portions 14b are located at a predetermined height with respect to the active layer 12. In the case of the optical functional element 120 of the optical integrated device 320 according to Embodiment 3, the surfaces of the terrace portions 14b are located at the same height as the surface of the etching stop layer 18 on the side of the contact layer 13. When the thickness of the etching stop layer 18 is dESL, the surfaces of the terrace portions 14b are located at a height of +dESL with reference to the surface of the active layer 12 on the side of the etching stop layer 18.

The above is an overview of each configuration of the optical functional element 120.

### Configuration of Optical Circuit Element in Optical Integrated Device According to Embodiment 3

The optical circuit element 220 according to Embodiment 3 has the same configuration as the optical circuit element 210 according to Embodiment 2. The lower cladding layer 22 is exposed in the top 26b of each protrusion portion 26 formed between the first recess 27a and each second recess 27b of the optical circuit element 220. That is, the outermost surface of the lower cladding layer 22 on the side that contacts the core layer 23 is exposed. Note that the upper cladding layer 25 and the core layer 23 are removed in an area that is at least as large as the optical functional element 120, and thus the outermost surface of the lower cladding layer 22 is exposed.

### Mounting Configuration of Optical Functional Element and Optical Circuit Element in Optical Integrated Device According to Embodiment 3

The above-mentioned optical functional element 120 and optical circuit element 220 are integrated by flip-chip mounting to form the optical integrated device 320. The mounting configuration of the optical functional element 120 and the optical circuit element 220 will be described below.

The optical functional element 120 is bonded to the optical circuit element 220 in an upside-down orientation so that the compound semiconductor substrate 11 is on top. That is, the optical functional element 120 and the optical circuit element 220 are flip-chip mounted. When performing flip-chip mounting, the center of the high-mesa section 16a of the optical functional element 120 is aligned with the center of the first recess 27a of the optical circuit element 220.

Each terrace portion 14b of the optical functional element 120 is in contact with the top 26b of each protrusion portion 26 formed between the first recess 27a and each second recess 27b of the optical circuit element 220.

The top surface of the high-mesa section 16a is bonded to the bottom of the first recess 27a. Specifically, the first electrode 17 formed on the top surface of the high-mesa section 16a and the second electrode 28 formed on the bottom of the first recess 27a are electrically and mechanically bonded to each other by a bonding member 30. Examples of the bonding member 30 include solder and conductive adhesive.

As described above, when the optical functional element 120 and the optical circuit element 220 are integrated by flip-chip mounting, the active layer 12 of the high-mesa section 16a on the side of the optical functional element 120 and the core layer 23 of the optical waveguide section 24 on the side of the optical circuit element 220 are optically coupled.

### Method for Manufacturing Optical Functional Element in Optical Integrated Device According to Embodiment 3

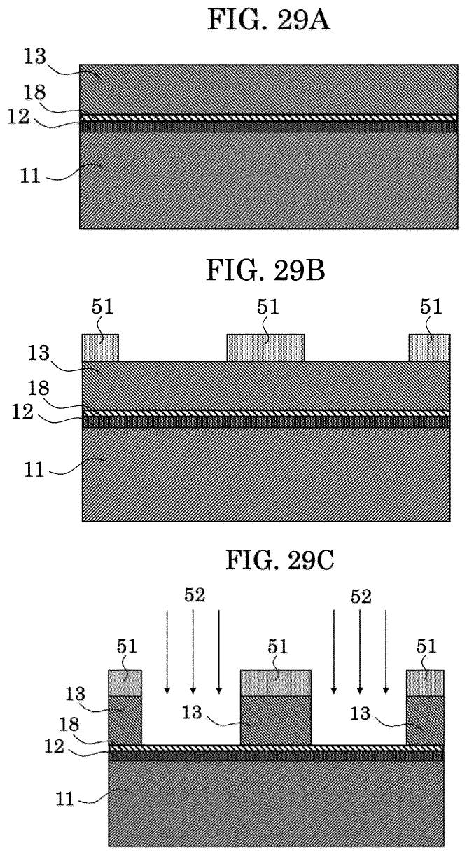

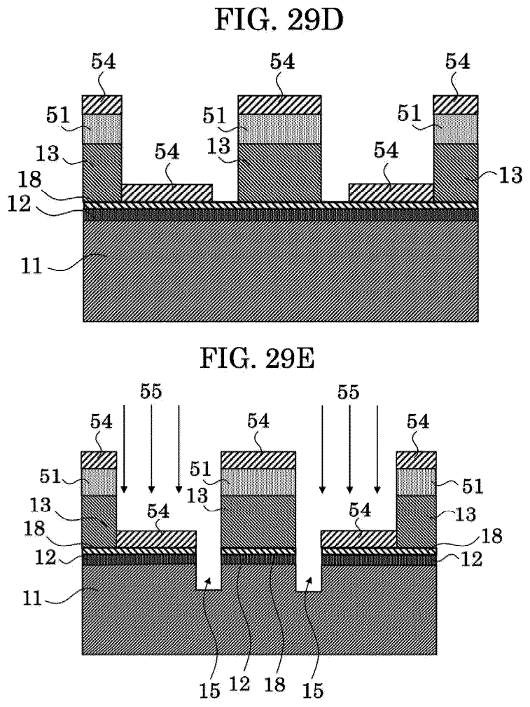

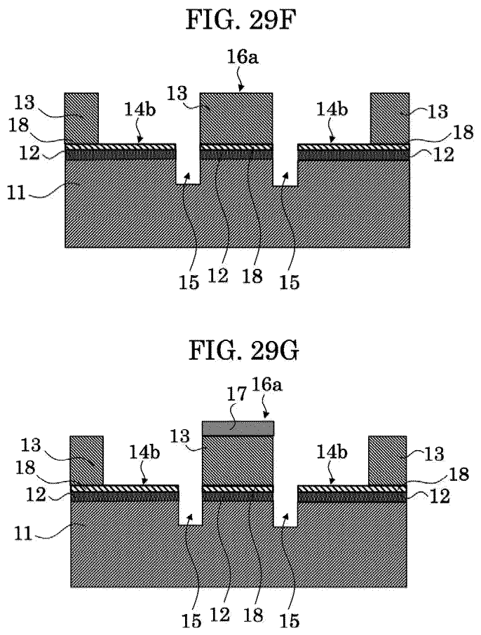

A method for manufacturing an optical functional element in the optical integrated device 320 according to Embodiment 3 will be described below with reference to FIGS. 29A to 29H.

First, as shown in FIG. 29A, the active layer 12 including an MQW made of InGaAsP having a composition ratio corresponding to a photoluminescence peak wavelength of 1.2 μm or more, or made of AlGaInAs having a composition ratio corresponding to a similar peak wavelength, the etching stop layer 18 made of AlInAs and having a thickness of 0.1 μm or less, and the contact layer 13 are sequentially epitaxially grown above the compound semiconductor substrate 11 made of, for example, InP. Examples of epitaxial crystal growth methods include MOCVD and MBE. The contact layer 13 is made of, for example, n-type or p-type doped InP.

After epitaxial crystal growth, as shown in FIG. 29B, a mask 51 made of an insulating film such as SiO₂ is formed using photolithography and etching techniques to protect the high-mesa section 16a and the non-terrace portion, that is, the portions other than the terrace portions 14b.

After formation of the mask 51, as shown in FIG. 29 C, the part of the contact layer 13 that is not covered by the mask 51 is selectively removed by reactive ion etching using dry etching 52 having high vertical property. After etching, the outermost surface of the etching stop layer 18 is exposed in the portion not covered by the mask 51. Methane gas, for example, is preferable as an etching gas used for dry etching 52. However, the etching gas is not limited to methane gas.

Next, as shown in FIG. 29D, a mask 54 made of an insulating film such as SiO₂ is formed to cover the part covered by the mask 51 and the terrace portions 14b. The mask 54 has an opening in the area where the mesa grooves 15 are to be formed.

After the formation of the mask 54, as shown in FIG. 29E, the etching stop layer 18, the active layer 12, and the part of compound semiconductor substrate 11 that are not covered by the mask 54 is removed by dry etching 55 having high vertical property again to form the mesa grooves 15, thereby completing the protruding-shaped high-mesa section 16a.

Next, as shown in FIG. 19G, the mask 51 and the mask 54 are removed by dry etching or wet etching.

Finally, as shown in FIG. 29G, the first electrode 17 is formed on the top surface of the high-mesa section 16a. Examples of metal materials constituting the first electrode 17 include Au, Ti, Pt, and the like. The first electrode 17 is formed by, for example, electron beam evaporation.

Through the above-mentioned manufacturing processes, the optical functional element 120 is completed.

### Method for Manufacturing Optical Circuit Element in Optical Integrated Device According to Embodiment 3

The optical circuit element 220 is manufactured by a known manufacturing method applying silicon processing technology. Consequently, the details of the manufacturing method of the optical circuit element 220 are omitted.

### Method for Manufacturing Optical Integrated Device According to Embodiment 3

The compound semiconductor substrate 11 of the optical functional element 120 is arranged in an upside-down orientation so that the compound semiconductor substrate 11 is on the upper side of the optical circuit element 220, and the center of the high-mesa section 16a of the optical functional element 120 is aligned with the center of the first recess 27a of the optical circuit element 220, and then the optical functional element 120 and the optical circuit element 220 are flip-chip mounted.

In the optical functional element 120 and the optical circuit element 220, each terrace portion 14b of the optical functional element 120 contacts the top 26a of each protrusion portion 26 formed between the first recess 27a and each second recess 27b of the optical circuit element 220. The first electrode 17 formed on the top surface of the high-mesa section 16 and the second electrode 28 formed on the bottom of the first recess 27a are electrically and mechanically bonded to each other by the bonding member 30.

Through the above-mentioned manufacturing processes, the optical integrated device 320 in which the optical functional element 120 and the optical circuit element 220 are flip-chip mounted is completed.

### Operation and Features of Optical Integrated Device According to Embodiment 3

Through the above-mentioned manufacturing processes for the optical functional element 120, the relative positional misalignment in the height direction between the optical functional element 120 and the optical circuit element 220 can be precisely controlled, especially by utilizing selective etching of AlInAs, which is a constituent material of the etching stop layer 18, and InP, which is a constituent material of the contact layer 13, by methane gas.

In contrast, in the case where the above-described height control method is used, the positions of the terrace portions 14b are limited to the interface between the etching stop layer 18 and the contact layer 13. Therefore, in Embodiment 3, in the optical circuit element 220, the upper cladding layer 25 and the core layer 23 of the top 26b of each protrusion portion 26, which is the region on which the optical functional element 120 is to be mounted, are selectively removed, so that the distance in the height direction between the active layer 12 of the high-mesa section 16a of the optical functional element 120 and the core layer 23 of the optical waveguide section 24 of the optical circuit element 220 substantially matches each other with sub-micron accuracy.

By applying such a structure as the optical functional element 120, since each terrace portion 14b located immediately above the active layer 12 of the optical functional element 120 and the top 26b of each protrusion portion 26 located immediately below the optical waveguide section 24 of the optical circuit element 220 are in contact with each other by flip-chip mounting, the relative positional misalignment in the height direction between the optical functional element 120 and the optical circuit element 220 is not larger than the relative positional misalignment in the height direction between the active layer 12 of the optical functional element 120 and the core layer 23 of the optical waveguide section 24 of the optical circuit element 220.

In the optical functional element 120 according to Embodiment 3, since the thickness of the etching stop layer 18 is set to 0.1 μm or less, the relative positional misalignment between the optical functional element 120 and the optical circuit element 220 in the height direction is reduced to 1 μm or less, which satisfies the requirement of about 0.5 μm, thus ensuring the achievement of high optical coupling efficiency.

In the optical integrated device 320 according to Embodiment 3, compared with the optical integrated devices 300, 310 according to Embodiments 1 and 2, the introduction of the etching stop layer 18 causes a disadvantage that optical loss occurs during light propagation or optical coupling between different optical elements due to the influence of deformation of the propagation light mode caused by the different refractive index region of the etching stop layer 18. However, selecting materials with high selectivity through etching has the effect of significantly reducing manufacturing errors in the manufacturing process of optical integrated devices.

### Effects of Embodiment 3

As described above, in the optical integrated device and the method for manufacturing the optical integrated device according to Embodiment 3, the surfaces of the terrace portions of the optical functional element are the uppermost surface of the etching stop layer, thereby the relative positional misalignment between the optical functional element and the optical circuit element in the height direction can be precisely controlled, thus providing an effect that the optical integrated device and the method for manufacturing the optical integrated device with high optical coupling efficiency can be obtained.

### Modification of Embodiment 3

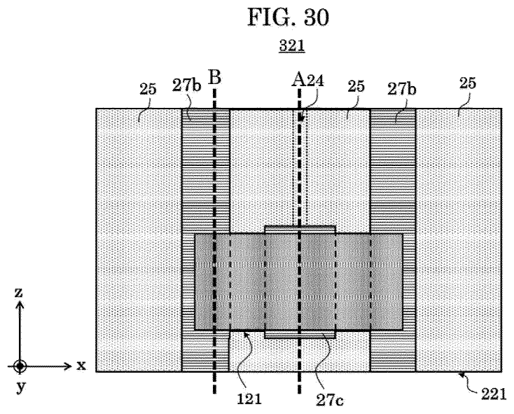

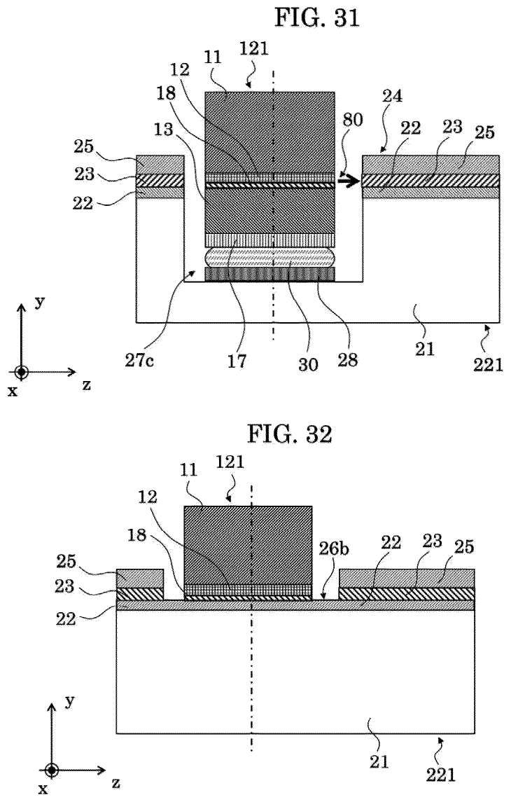

FIG. 30 is a top view showing the structure of an optical integrated device 321 according to Modification of Embodiment 3. FIG. 31 is a cross-sectional view along line A in FIG. 30 for the optical integrated device 321 according to Modification of Embodiment 3. FIG. 32 is a cross-sectional view along line B in FIG. 30 for the optical integrated device 321 according to Modification of Embodiment 3. In FIGS. 30 to 32, the xyz axis directions are shown for convenience of explanation.

The optical integrated device 321 according to Modification of Embodiment 3 differs from the optical integrated device 320 according to Embodiment 3 in that one of the four sides of the first recess 27 a provided in the optical circuit element 220 of the optical integrated device 320 has an opening, whereas in the optical integrated device 321 according to Modification of Embodiment 3, no opening is provided in any of the four sides of the first recess 27c provided in the optical circuit element 221. That is, in the configuration in which the optical functional element 121 and the optical circuit element 221 are flip-chip mounted, the high-mesa section 16a of the optical functional element 121 enters into the first recess 27c, and the periphery thereof is surrounded by the sides of the first recess 27c.

In the optical integrated device 321 according to Modification of Embodiment 3, in addition to the propagation direction 80 of the light emitted from the high-mesa section 16a of the optical functional element 121 toward the optical waveguide section 24 of the optical circuit element 221, the light emitted from the other end face of the high-mesa section 16a is also waveguided into the optical circuit element 221 so that the optical integrated device 321 can achieve even higher functionality.

### Effects of Modification of Embodiment 3

As described above, in the optical integrated device according to Modification of Embodiment 3, the surfaces of the terrace portions of the optical functional element are the uppermost surface of the etching stop layer, thereby the relative positional misalignment between the optical functional element and the optical circuit element in the height direction can be precisely controlled, thus providing an effect of obtaining an optical integrated device with high optical coupling efficiency. Furthermore, the light emitted from the other end face of the high-mesa section of the optical functional element can be also utilized, thus providing an effect of achieving even higher functionality of the optical integrated device.

### Embodiment 4

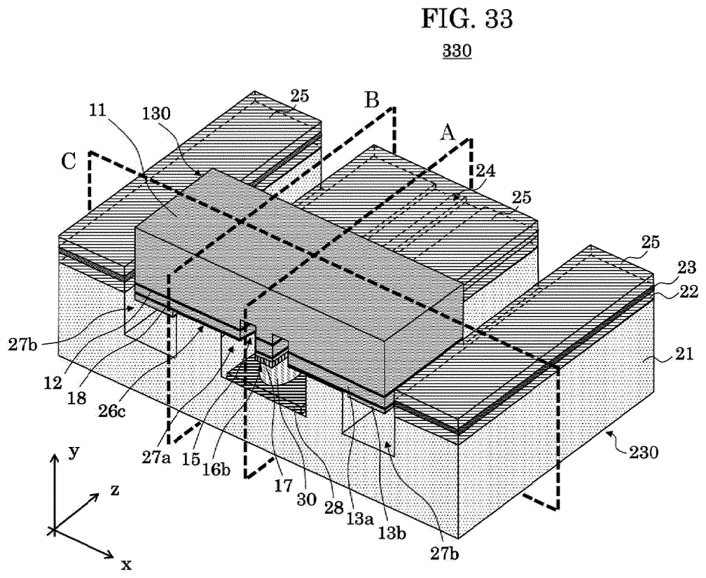

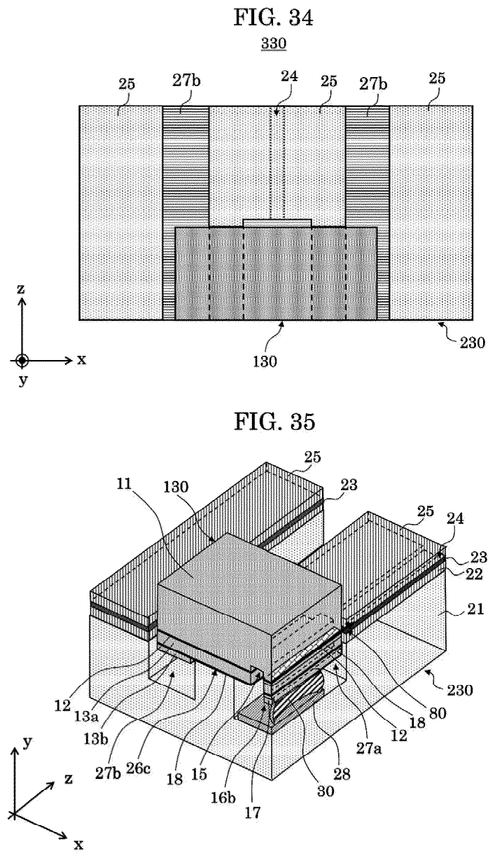

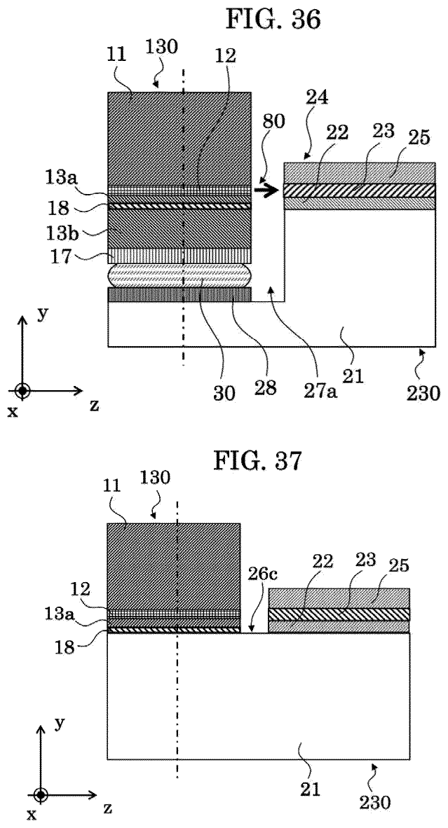

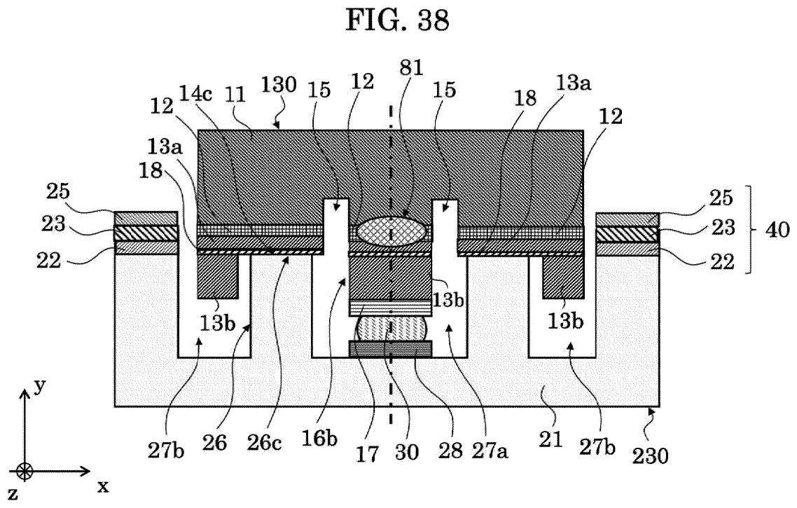

FIG. 33 is an overview diagram showing a structure of an optical integrated device 330 according to Embodiment 4. FIG. 34 is a top view showing the structure of the optical integrated device 300 according to Embodiment 1. FIG. 35 is an overview diagram showing the optical integrated device 330 according to Embodiment 4 as viewed from a cross section along line A in FIG. 33. FIG. 36 is a cross-sectional view along line A in FIG. 33 for the optical integrated device 330 according to Embodiment 4. FIG. 37 is a cross-sectional view along line B in FIG. 33 for the optical integrated device 330 according to Embodiment 4. FIG. 38 is a cross-sectional view along line C in FIG. 33 for the optical integrated device 330 according to Embodiment 4. In FIGS. 33 to 38, the xyz axis directions are shown for convenience of explanation. FIG. 38 schematically shows the spread 81 of the optical mode propagating through a high-mesa section 16b of an optical functional element 130.

### Configuration of Optical Integrated Device According to Embodiment 4

The optical integrated device 330 comprises an optical functional element 130 and an optical circuit element 230. The optical functional element 130 is made of a compound semiconductor material such as InP, for example. The optical circuit element 230 is made of a semiconductor material such as Si, for example.

### Structure of Optical Functional Element of Optical Integrated Device According to Embodiment 4

The optical functional element 100 includes: an active layer 12 and a contact layer 13 formed above a compound semiconductor substrate 11; a protruding-shaped high-mesa section 16b that includes a part of the compound semiconductor substrate 11 and comprises at least the active layer 12, a first contact layer 13a, an etching stop layer 18, and a second contact layer 13b from the side of the compound semiconductor substrate 11; a first electrode 17 formed on the top surface of the high-mesa section 16b; and planar-shaped terrace portions 14c that are provided along the high-mesa section 16b and are positioned at a predetermined height with respect to the active layer 12.

The first contact layer 13a and the second contact layer 13b are made of the same compound semiconductor material, InP. The etching stop layer 18 is formed on the first contact layer 13a and is made of a compound semiconductor material such as, for example, AlInAs which exhibits a reactivity different from that of the second contact layer 13b in a specific etching process. In the following description, only the parts structurally different from the optical functional element 100 of the optical integrated device 300 according to Embodiment 1 will be described.

The terrace portions 14c are provided along the stripe-shaped high-mesa section 16b through the respective mesa grooves 15. The terrace portions 14c have a planar shape. The surfaces of the terrace portions 14c are the uppermost surface of the etching stop layer 18. That is, the height of the surface of the terrace portions 14c coincides with the height of the interface between the etching stop layer 18 and the second contact layer 13b. The terrace portions 14c are formed by removing the second contact layer 13b above the etching stop layer 18 using selective etching or the like.

Since the terrace portions 14c are configured as described above, the surfaces of the terrace portions 14c are located at a predetermined height with respect to the active layer 12. In the case of the optical functional element 130 of the optical integrated device 330 according to Embodiment 4, the surfaces of the terrace portions 14c are located at the same height as the surface of the etching stop layer 18 on the side of the second contact layer 13b. When the thickness of the first contact layer 13a is d_{CN1} and the thickness of the etching stop layer 18 is d_{ESL}, the surfaces of the terrace portions 14c are located at a height of d_{CN1}+d_{ESL} with reference to the surface of the active layer 12 on the side of the first contact layer 13a.

The above is an overview of each configuration of the optical functional element 130.

### Configuration of Optical Circuit Element in Optical Integrated Device According to Embodiment 4

The semiconductor substrate 21 is exposed in the top 26c of each protrusion portion 26 formed between the first recess 27a and each second recess 27 b of the optical circuit element 230 according to Embodiment 4. That is, the interface of the semiconductor substrate 21 on the side that contacts the lower cladding layer 22 is exposed. Note that the lower cladding layer 22, the core layer 23, and the upper cladding layer 25 are removed in an area that is at least as large as the optical functional element 130, and thus the semiconductor substrate 21 is exposed.

### Mounting Configuration of Optical Functional Element and Optical Circuit Element in Optical Integrated Device According to Embodiment 4

The above-mentioned optical functional element 130 and optical circuit element 230 are integrated by flip-chip mounting to form the optical integrated device 330. The mounting configuration of the optical functional element 130 and the optical circuit element 230 will be described below.

The optical functional element 130 is bonded to the optical circuit element 230 in an upside-down orientation so that the compound semiconductor substrate 11 is on top. That is, the optical functional element 130 and the optical circuit element 230 are flip-chip mounted. When performing flip-chip mounting, the center of the high-mesa section 16b of the optical functional element 130 is aligned with the center of the first recess 27a of the optical circuit element 230.

Each terrace portion 14c of the optical functional element 130 is in contact with the top 26b of each protrusion portion 26 formed between the first recess 27a and each second recess 27b of the optical circuit element 230.

The top surface of the high-mesa section 16b is bonded to the bottom of the first recess 27a. Specifically, the first electrode 17 formed on the top surface of the high-mesa section 16b and the second electrode 28 formed on the bottom of the first recess 27a are electrically and mechanically bonded to each other by a bonding member 30. Examples of the bonding member 30 include solder and conductive adhesive.

As described above, when the optical functional element 130 and the optical circuit element 230 are integrated by flip-chip mounting, the active layer 12 of the high-mesa section 16b on the side of the optical functional element 130 and the core layer 23 of the optical waveguide section 24 on the side of the optical circuit element 230 are optically coupled.

In FIGS. 35 and 36, when the optical functional element 130 is a light-emitting device such as a semiconductor laser or an SOA, the light propagation direction 80 is indicated by arrows. FIG. 38 schematically shows the spread 81 of the optical mode propagating through the high-mesa section 16b of the optical functional element 130.

### Operation and Features of Optical Integrated Device According to Embodiment 4

Through the above-mentioned manufacturing processes for the optical functional element 130, the relative positional misalignment in the height direction between the optical functional element 130 and the optical circuit element 230 can be precisely controlled, especially by utilizing selective etching of AlInAs, which is a constituent material of the etching stop layer 18, and InP, which is a constituent material of the second contact layer 13b, by methane gas.

In contrast, in the case where the above-described height control method is used, the positions of the terrace portions 14c are limited to the interface between the etching stop layer 18 and the second contact layer 13b. Therefore, in Embodiment 4, the thickness of the first contact layer 13 a of the optical functional element 130 is set to be the same as the thickness of the lower cladding layer 22 of the optical circuit element 230, and in the optical circuit element 230, the lower cladding layer 22, the core layer 23, and the upper cladding layer 25 of the top 26c of each protrusion portion 26, which is the region on which the optical functional element 120 is to be mounted, are selectively removed, so that the distance in the height direction between the active layer 12 of the high-mesa section 16b of the optical functional element 120 and the core layer 23 of the optical waveguide section 24 of the optical circuit element 230 substantially matches each other with sub-micron accuracy.

By applying such a structure as the optical functional element 130, since each terrace portion 14c located immediately above the etching stop layer 18 of the optical functional element 130 and the top 26c of each protrusion portion 26 located immediately below the optical waveguide section 24 of the optical circuit element 230 are in contact with each other by flip-chip mounting, the relative positional misalignment in the height direction between the optical functional element 130 and the optical circuit element 230 is not larger than the relative positional misalignment in the height direction between the optical functional element 130 and the optical circuit element 230 is not larger than the total thickness of the active layer 12, the etching stop layer 18, and the first contact layer 13a of the optical functional element 130, and the total thickness of the lower cladding layer 22 and the core layer 23 of the optical circuit element 230.

In the optical functional element 130 of Embodiment 4, the thickness of the etching stop layer 18 is set to 0.1 μm or less, and the variation in the thickness of the first contact layer 13a can be suppressed to about ±0.1 μm by high-precision layer thickness control during epitaxial crystal growth. Moreover, the variation in the thickness of the lower cladding layer 22 of the optical circuit element 230 can be controlled to within approximately ±0.1 μm in the case where the general BOX layer thickness of a few um and layer thickness tolerance of ±5% used in SOI substrates, or the like, are applied.

On the basis of the above numerical values regarding the variation in the layer thickness, the relative position of the optical functional element 130 and the optical circuit element 230 in the height direction is reduced to 1 μm or less, which satisfies the requirement of about 0.5 μm, thus ensuring the achievement of high optical coupling efficiency.

In the optical integrated device 330 according to Embodiment 4, as compared with Embodiments 1 to 3, since the accuracy of the relative position between the optical functional element 130 and the optical circuit element 230 in the height direction is added to the variation in the thicknesses of the first contact layer 13a and the lower cladding layer 22, which may be a disadvantage from the viewpoint of the accuracy of the alignment in the height direction. However, the active layer 12 of the high-mesa section 16b for guiding light can be provided apart from the etching stop layer 18 by the thickness of the first contact layer 13a, thus providing an effect of avoiding the problem that optical loss occurs during light propagation or optical coupling between different optical elements due to the influence of the deformation of the propagation light mode caused by the different refractive index regions of the etching stop layer 18.

### Effects of Embodiment 4

As described above, in the optical integrated device and the method for manufacturing the optical integrated device according to Embodiment 4, the surfaces of the terrace portions of the optical functional element are the uppermost surface of the etching stop layer and the active layer and the etching stop layer are separated from each other, thereby the relative positional misalignment of the optical functional element and the optical circuit element in the height direction can be precisely controlled, and the influence of the etching stop layer on the propagation light can be reduced, thus providing an effect that the optical integrated device and the method for manufacturing the optical integrated device with high optical coupling efficiency can be obtained.

### Modification of Embodiment 4

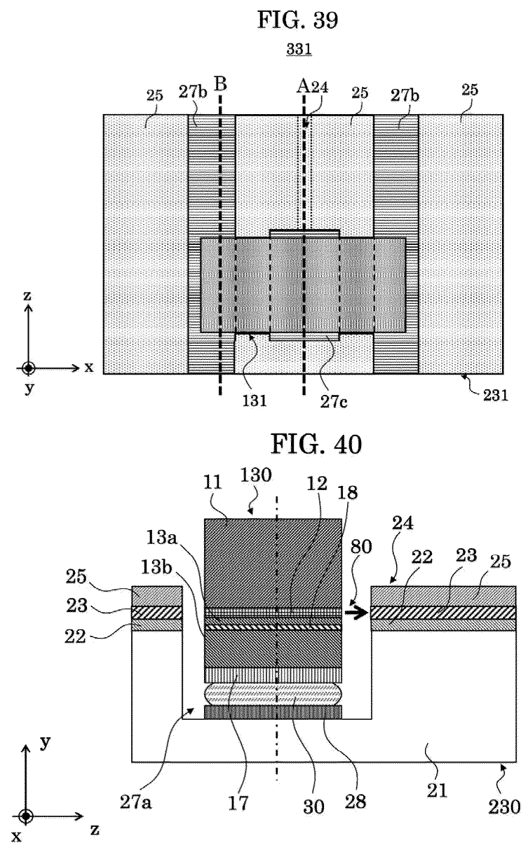

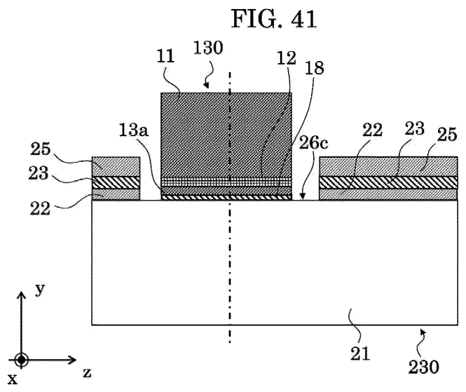

FIG. 39 is a top view showing the structure of an optical integrated device 331 according to Modification of Embodiment 4. FIG. 40 is a cross-sectional view along line A in FIG. 39 for the optical integrated device 331 according to Modification of Embodiment 4. FIG. 41 is a cross-sectional view along line B in FIG. 39 for the optical integrated device 331 according to Modification of Embodiment 4. In FIGS. 39 to 41, the xyz axis directions are shown for convenience of explanation.

The optical integrated device 331 according to Modification of Embodiment 4 differs from the optical integrated device 330 according to Embodiment 4 in that one of the four sides of the first recess 27 a provided in the optical circuit element 230 of the optical integrated device 330 has an opening, whereas in the optical integrated device 331 according to Modification of Embodiment 4, no opening is provided in any of the four sides of the first recess 27c provided in the optical circuit element 231. That is, in the configuration in which the optical functional element 131 and the optical circuit element 231 are flip-chip mounted, the high-mesa section 16b of the optical functional element 131 enters into the first recess 27c, and the periphery thereof is surrounded by the sides of the first recess 27c.

In the optical integrated device 331 according to Modification of Embodiment 4, in addition to the propagation direction 80 of the light emitted from the high-mesa section 16b of the optical functional element 131 toward the optical waveguide section 24 of the optical circuit element 231, the light emitted from the other end face of the high-mesa section 16b is also waveguided into the optical circuit element 231 so that the optical integrated device 331 can achieve even higher functionality.

### Effects of Modification of Embodiment 4

As described above, in the optical integrated device according to Modification of Embodiment 4, the surfaces of the terrace portions of the optical functional element are the uppermost surface of the etching stop layer, and the active layer and the etching stop layer are separated from each other, thereby the relative positional misalignment between the optical functional element and the optical circuit element in the height direction can be precisely controlled, thus providing an effect of obtaining an optical integrated device with high optical coupling efficiency. Furthermore, the light emitted from the other end face of the high-mesa section of the optical functional element can be also utilized, thus providing an effect of achieving even higher functionality of the optical integrated device.

### Embodiment 5

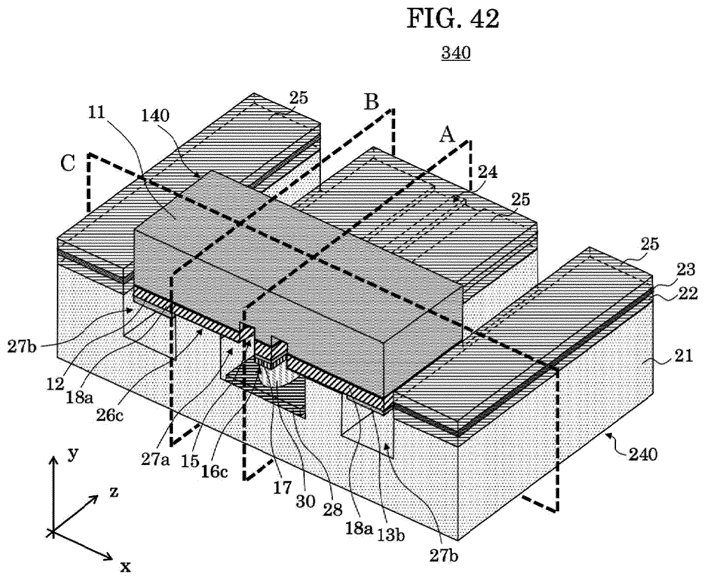

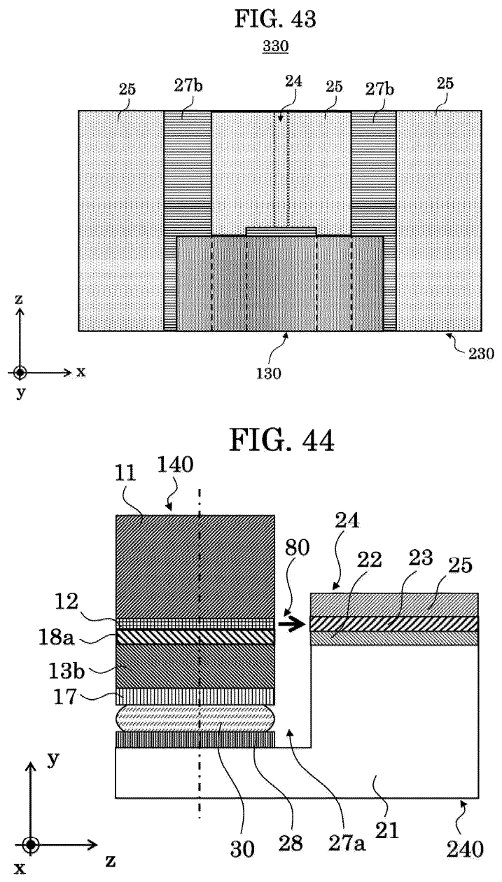

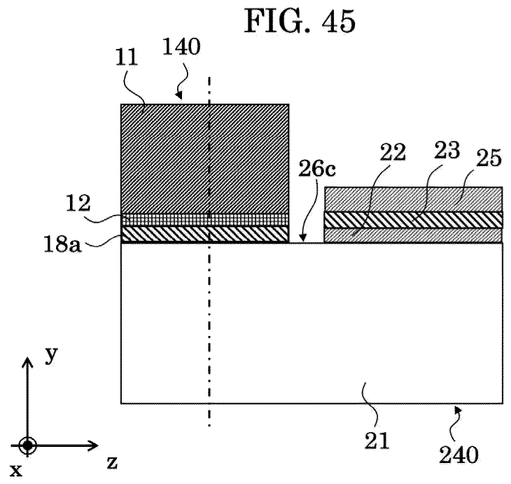

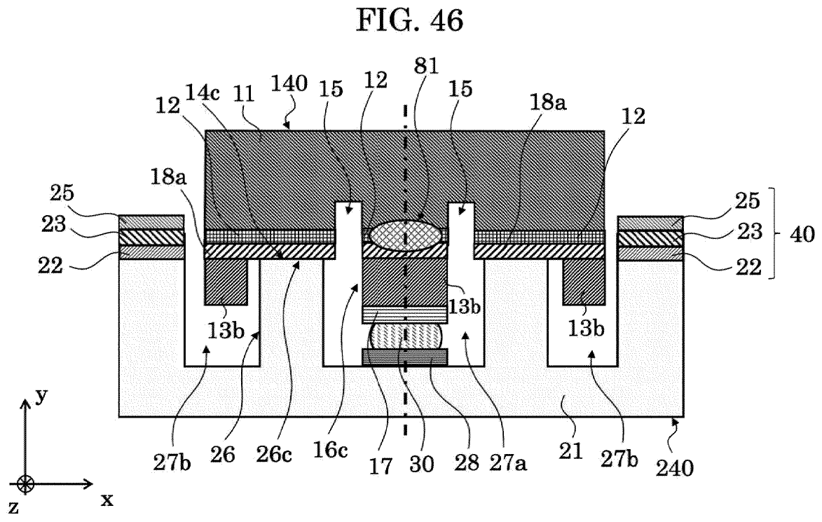

FIG. 42 is an overview diagram showing a structure of an optical integrated device 340 according to Embodiment 5. The optical integrated device 340 according to Embodiment 5 comprises an optical functional element 140 and an optical circuit element 240. FIG. 43 is a top view showing the structure of the optical integrated device 340 according to Embodiment 5. FIG. 44 is a cross-sectional view along line A in FIG. 42 for the optical integrated device 340 according to Embodiment 5. FIG. 45 is a cross-sectional view along line B in FIG. 42 for the optical integrated device 340 according to Embodiment 5. FIG. 46 is a cross-sectional view along line C in FIG. 42 for the optical integrated device 340 according to Embodiment 5.

### Structure of Optical Functional Element of Optical Integrated Device According to Embodiment 5

As shown in the cross-sectional views of FIG. 44, FIG. 45, and FIG. 46, the optical integrated device 340 according to Embodiment 5 is characterized in that there is no first contact layer 13a between the etching stop layer 18a and the active layer 12 in the optical functional element 140, and instead, the thickness of the etching stop layer 18a is thickened by the same thickness as that of the first contact layer 13a.

In the optical integrated device 340 according to Embodiment 5, the layer structure of the high-mesa section 16c in the optical functional element 140 is reduced by one layer, that is, the thickness of the first contact layer 13a is reduced, so that the manufacturing of the optical integrated device is easier than that of Embodiment 4. Furthermore, making the thickness of the etching stop layer 18a sufficiently thick allows the etching stop layer 18a itself to function as a cladding layer. Therefore, the interface between the etching stop layer 18a and the first contact layer 13a, which have different refractive indices, no longer exists in the mode distribution of the propagating light, so that it is possible to suppress the deformation of the propagating light mode to a small extent, thus providing an effect of avoiding the problem of optical loss occurring during optical coupling between different optical elements.

### Effects of Embodiment 5

As described above, in the optical integrated device and the method for manufacturing the optical integrated device according to Embodiment 5, the surfaces of the terrace portions of the optical functional element are the uppermost surface of the etching stop layer and the thickness control is performed by the etching stop layer, thereby the relative positional misalignment of the optical functional element and the optical circuit element in the height direction can be precisely controlled, thus providing an effect that an optical integrated device with high optical coupling efficiency can be obtained and in addition, such optical integrated device can be easily manufactured.

### Modification of Embodiment 5

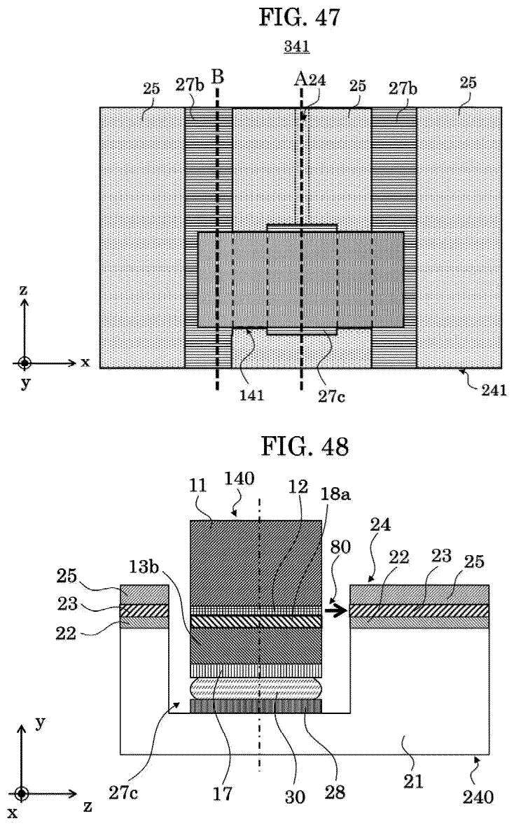

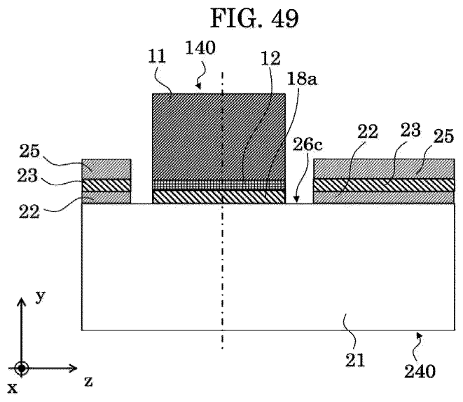

FIG. 47 is a top view showing the structure of an optical integrated device 341 according to Modification of Embodiment 5. FIG. 48 is a cross-sectional view along line A in FIG. 47 for the optical integrated device 341 according to Modification of Embodiment 5. FIG. 49 is a cross-sectional view along line B in FIG. 47 for the optical integrated device 341 according to Modification of Embodiment 5. In FIGS. 47 to 49, the xyz axis directions are shown for convenience of explanation.

The optical integrated device 341 according to Modification of Embodiment 5 differs from the optical integrated device 340 according to Embodiment 5 in that one of the four sides of the first recess 27 a provided in the optical circuit element 240 of the optical integrated device 340 has an opening, whereas in the optical integrated device 341 according to Modification of Embodiment 5, no opening is provided in any of the four sides of the first recess 27c provided in the optical circuit element 241. That is, in the configuration in which the optical functional element 141 and the optical circuit element 241 are flip-chip mounted, the high-mesa section 16c of the optical functional element 141 enters into the first recess 27c, and the periphery thereof is surrounded by the sides of the first recess 27c.

In the optical integrated device 341 according to Modification of Embodiment 5, in addition to the propagation direction 80 of the light emitted from the high-mesa section 16c of the optical functional element 141 toward the optical waveguide section 24 of the optical circuit element 241, the light emitted from the other end face of the high-mesa section 16c is also waveguided into the optical circuit element 241 so that the optical integrated device 341 can achieve even higher functionality.

### Effects of Modification of Embodiment 5

As described above, in the optical integrated device according to Modification of Embodiment 5, the surfaces of the terrace portions of the optical functional element are the uppermost surface of the etching stop layer and the thickness control is performed by the etching stop layer, thereby the relative positional misalignment between the optical functional element and the optical circuit element in the height direction can be precisely controlled, thus providing an effect of obtaining an optical integrated device with high optical coupling efficiency. Furthermore, the light emitted from the other end face of the high-mesa section of the optical functional element can be also utilized, thus providing an effect of achieving even higher functionality of the optical integrated device.

### Embodiment 6

### Structure and Features of Optical Functional Element in Optical Integrated Device According to Embodiment 6

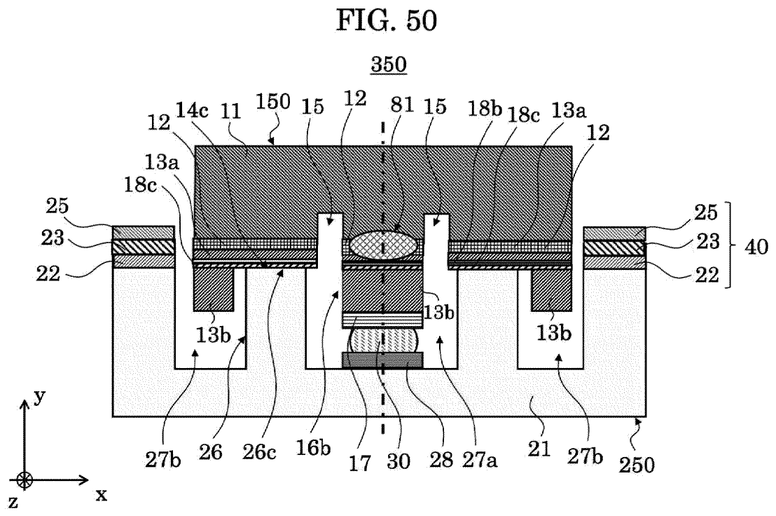

Embodiment 6 is a modification of Embodiments 3 to 4. FIG. 50 is a cross-sectional view of an optical integrated device 350 according to Embodiment 6. The optical integrated device 350 according to Embodiment 6 comprises an optical functional element 150 and an optical circuit element 250. The optical integrated device 350 according to Embodiment 6 is characterized in that the etching stop layer comprises a stacked structure consisting of at least two or more layers of AlInAs having different compositions. An example of the stacked structure for the etching stop layer is a layer including an Al (0.48) In (0.52) As composition that is lattice-matched to an InP substrate, and a layer composed of an Al (0.7) In (0.3) As composition that contains more Al than the above, for example.

As a specific example of the two-layer etching stop layer, the first etching stop layer 18b on the side close to the active layer 12 is a layer with the Al (0.48) In (0.52) As composition, and the second etching stop layer 18c on the side far from the active layer 12 is a layer with the Al (0.7) In (0.3) As composition.

Since the optical integrated device 350 according to Embodiment 6 includes a layer made of AlInAs composition which is out of the lattice-matched condition with the InP substrate, there is a possibility that distortion occurs in the crystal, causing problems in crystal quality, reliability, and the like. However, when the etching stop layer comprises a layer with a composition that contains a larger amount of aluminum (Al) as a stacked structure, the oxidation phenomenon of Al is more pronounced in dry etching with methane gas, enabling a larger etching selectivity with InP, thus improving the function of the etching stop layer.

Furthermore, since the layer containing a larger amount of Al has a lower refractive index, the refractive index of the first etching stop layer 18b on the side close to the active layer 12 is higher, and the refractive index of the second etching stop layer 18c on the side far from the active layer 12 is lower. Therefore, the two layers have the relationship of the core layer and the cladding layer in the optical waveguide section, and thus it is possible to suppress the deformation of the propagating light mode to a small extent, thus providing an effect of avoiding the problem of optical loss occurring during optical coupling between different optical elements.

### Effects of Embodiment 6

As described above, in the optical integrated device and the method for manufacturing the optical integrated device according to Embodiment 6, the etching stop layer has a stacked structure, thereby the relative positional misalignment of the optical functional element and the optical circuit element in the height direction can be precisely controlled, thus providing an effect that an optical integrated device with high optical coupling efficiency can be obtained and in addition, such optical integrated device can be easily manufactured.

### Embodiment 7

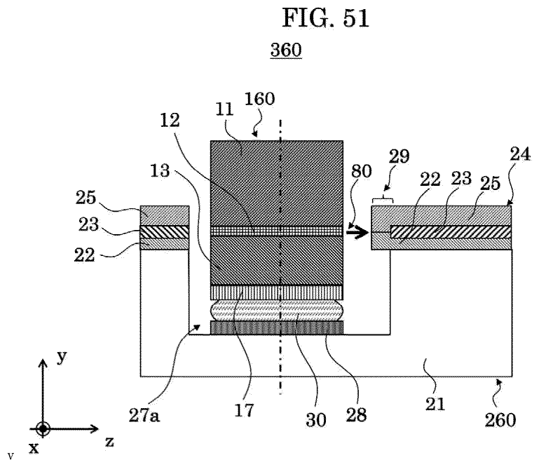

Embodiment 7 is a modification of Embodiments 1 to 6. FIG. 51 is a cross-sectional view of an optical integrated device 360 according to Embodiment 7. The optical integrated device 360 according to Embodiment 7 comprises an optical functional element 160 and an optical circuit element 260. The optical integrated device 360 according to embodiment 7 has the following features. The tip of the core layer 23 of the optical waveguide section 24 formed in the optical circuit element 260 has a tapered shape that continuously tapers down in the x-direction toward the front surface facing the optical functional element 160. The tip of the optical waveguide section 24 further has a rectangular xy cross-sectional shape in which the upper cladding layer 25 and the lower cladding layer 22 are integrated from the tip of the optical waveguide section 24, and the x-direction layer thickness is the sum of the thicknesses of the upper cladding layer 25 and lower cladding layer 22. Furthermore, a second optical waveguide section 29 is formed using a core and air as the cladding material.

In the optical integrated device 360 according to Embodiment 7, the second optical waveguide section 29 having a lower refractive index is formed at the tip of the optical waveguide section 24 of the optical circuit element 260 to function as a so-called spot size converter (SSC) that expands the mode diameter of the propagation light. Applying the spot size converter structure enables the tolerance of optical coupling efficiency to be relaxed for misalignment in the mounting position between the optical functional element 160 and the optical circuit element 260.

In the above description, the structure in which the SSC is provided on the optical circuit element 260 is given as an example, but the SSC may be provided not only on the side of the optical circuit element 260 but also on the side of the optical functional element 160. The structure of the SSC need not be limited to the one example of Embodiment 7. For example, SiN or SiON material may be used instead of SiO₂. Furthermore, a tapered shape may be simply provided at the tip of the core layer 23 of the optical waveguide section 24 without forming the second optical waveguide section 29.

### Effects of Embodiment 7

As described above, according to the optical integrated device according to Embodiment 7, the SSC is provided on either the optical functional element side or the optical circuit element side, thereby the optical coupling efficiency tolerance against the misalignment of the mounting position can be relaxed, thus providing an effect that an optical integrated device with high optical coupling efficiency can be obtained.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

11 compound semiconductor substrate
12 active layer
13 contact layer
13a first contact layer
13b second contact layer
14, 14a, 14b, 14c terrace portion
15 mesa groove
16, 16a, 16b, 16c high-mesa section
17 first electrode
18, 18a etching stop layer
18b first etching stop layer
18c second etching stop layer
21 semiconductor substrate
22 lower cladding layer
23 core layer
24 optical waveguide section
25 upper cladding layer
26 protrusion portion
26a, 26b, 26c top
27a, 27c first recess
27b second recess
28 second electrode
29 second optical waveguide
30 bonding member
40 stacked structure substrate
51,54 mask
52, 55 dry etching
53 mixed solution
80 light propagation direction
81 spread of optical mode
100, 101, 110, 111, 120, 121, 130, 131, 140, 141, 150, 160 optical functional element
200, 201, 210, 211, 220, 221, 230, 231, 240, 241, 250, 260 optical circuit element
300, 301, 310, 311, 320, 321, 330, 331, 340, 341, 350, 360 optical integrated device

1.-15. (canceled)

16. An optical integrated device that integrates an optical functional element and an optical circuit element, the optical integrated device comprising:
an optical functional element, the optical functional element including:
a compound semiconductor substrate;
a protruding-shaped high-mesa section that includes a part of the compound semiconductor substrate, the high-mesa section including at least an active layer and a contact layer from the side of the compound semiconductor substrate; and
planar-shaped terrace portions provided along the high-mesa section,
an optical circuit element, the optical circuit element including:
a semiconductor substrate;
a lower cladding layer, a core layer and an upper cladding layer formed above the semiconductor substrate;
a first recess provided in the semiconductor substrate;
second recesses that are provided along the side surfaces of the first recess and are separated from the side surfaces of the first recess;
protrusion portions formed between the first recess and each second recesses; and
an optical waveguide section including the lower cladding layer, the core layer and the upper cladding layer, the optical waveguide section being provided in contact with a side surface that is different from the side surface of the first recess and the side surface opposite the side surface of the first recess; wherein
the surface height of each terrace portion is set at the interface between the compound semiconductor substrate and the active layer, and
the height of the top of each protrusion portion is set at the surface of the core layer on the side of the upper cladding layer, and
the surface of each terrace portion is contact with the top of each protrusion portion, and
the active layer of the high-mesa section is optically coupled to the core layer of the optical waveguide section.

17. An optical integrated device that integrates an optical functional element and an optical circuit element, the optical integrated device comprising:
an optical functional element, the optical functional element including:
a compound semiconductor substrate;
a protruding-shaped high-mesa section that includes a part of the compound semiconductor substrate, the high-mesa section including at least an active layer and a contact layer from the side of the compound semiconductor substrate; and
planar-shaped terrace portions provided along the high-mesa section,
an optical circuit element, the optical circuit element including:
a semiconductor substrate;
a lower cladding layer, a core layer and an upper cladding layer formed above the semiconductor substrate;
a first recess provided in the semiconductor substrate;
second recesses that are provided along the side surfaces of the first recess and are separated from the side surfaces of the first recess;
protrusion portions formed between the first recess and each second recesses; and
an optical waveguide section including the lower cladding layer, the core layer and the upper cladding layer, the optical waveguide section being provided in contact with a side surface that is different from the side surface of the first recess and the side surface opposite the side surface of the first recess; wherein
the surface height of each terrace portion is set at the interface between the active layer and the contact layer, and
the height of the top of each protrusion portion is set at the surface of the core layer on the side of the lower cladding layer, and
the surface of each terrace portion is contact with the top of each protrusion portion, and
the active layer of the high-mesa section is optically coupled to the core layer of the optical waveguide section.

18. An optical integrated device that integrates an optical functional element and an optical circuit element, the optical integrated device comprising:
an optical functional element, the optical functional element including:
a compound semiconductor substrate;
a protruding-shaped high-mesa section that includes a part of the compound semiconductor substrate, the high-mesa section including at least an active layer, a contact layer, and an etching stop layer provided between the active layer and the contact layer from the side of the compound semiconductor substrate; and
planar-shaped terrace portions provided along the high-mesa section,
an optical circuit element, the optical circuit element including:
a semiconductor substrate;
a lower cladding layer, a core layer and an upper cladding layer formed above the semiconductor substrate;
a first recess provided in the semiconductor substrate;
second recesses that are provided along the side surfaces of the first recess and are separated from the side surfaces of the first recess;
protrusion portions formed between the first recess and each second recesses; and
an optical waveguide section including the lower cladding layer, the core layer and the upper cladding layer, the optical waveguide section being provided in contact with a side surface that is different from the side surface of the first recess and the side surface opposite the side surface of the first recess; wherein
the surface height of each terrace portion is set at the interface between the contact layer and the etching stop layer, and
the height of the top of each protrusion portion is set at the surface of the lower cladding layer on the side of the core layer, and
the surface of each terrace portion is contact with the top of each protrusion portion, and
the active layer of the high-mesa section is optically coupled to the core layer of the optical waveguide section.

19. An optical integrated device that integrates an optical functional element and an optical circuit element, the optical integrated device comprising:
an optical functional element, the optical functional element including:
a compound semiconductor substrate;
a protruding-shaped high-mesa section that includes a part of the compound semiconductor substrate, the high-mesa section including at least an active layer, a first contact layer, an etching stop layer, and a second contact layer from the side of the compound semiconductor substrate; and
planar-shaped terrace portions provided along the high-mesa section,
an optical circuit element, the optical circuit element including:
a semiconductor substrate;
a lower cladding layer, a core layer and an upper cladding layer formed above the semiconductor substrate;
a first recess provided in the semiconductor substrate;
second recesses that are provided along the side surfaces of the first recess and are separated from the side surfaces of the first recess;
protrusion portions formed between the first recess and each second recesses; and
an optical waveguide section including the lower cladding layer, the core layer and the upper cladding layer, the optical waveguide section being provided in contact with a side surface that is different from the side surface of the first recess and the side surface opposite the side surface of the first recess; wherein
the surface height of each terrace portion is set at the interface between the etching stop layer and the second contact layer, and
the height of the top of each protrusion portion is set at the interface between the semiconductor substrate and the lower cladding layer, and
the thickness of the etching stop layer and the thickness of the lower cladding layer is set to be equal, and
the surface of each terrace portion is contact with the top of each protrusion portion, and
the active layer of the high-mesa section is optically coupled to the core layer of the optical waveguide section.

20. An optical integrated device that integrates an optical functional element and an optical circuit element, the optical integrated device comprising:
an optical functional element, the optical functional element including:
a compound semiconductor substrate;
a protruding-shaped high-mesa section that includes a part of the compound semiconductor substrate, the high-mesa section including at least an active layer, a contact layer, and an etching stop layer provided between the active layer and the contact layer from the side of the compound semiconductor substrate; and
planar-shaped terrace portions provided along the high-mesa section,
an optical circuit element, the optical circuit element including:
a semiconductor substrate;
a lower cladding layer, a core layer and an upper cladding layer formed above the semiconductor substrate;
a first recess provided in the semiconductor substrate;
second recesses that are provided along the side surfaces of the first recess and are separated from the side surfaces of the first recess;
protrusion portions formed between the first recess and each second recesses; and
an optical waveguide section including the lower cladding layer, the core layer and the upper cladding layer, the optical waveguide section being provided in contact with a side surface that is different from the side surface of the first recess and the side surface opposite the side surface of the first recess; wherein
the surface height of each terrace portion is set at the interface between the etching stop layer and the contact stop layer, and
the height of the top of each protrusion portion is set at the interface between the semiconductor substrate and the lower cladding layer, and
the thickness of the etching stop layer and the thickness of the lower cladding layer is set to be equal, and
the surface of each terrace portion is contact with the top of each protrusion portion, and
the active layer of the high-mesa section is optically coupled to the core layer of the optical waveguide section.

21. An optical integrated device that integrates an optical functional element and an optical circuit element, the optical integrated device comprising:
an optical functional element, the optical functional element including:
a compound semiconductor substrate;
a protruding-shaped high-mesa section that includes a part of the compound semiconductor substrate, the high-mesa section including at least an active layer, a first contact layer, a first etching stop layer, a second etching stop layer, and a second contact layer from the side of the compound semiconductor substrate; and
planar-shaped terrace portions provided along the high-mesa section,
an optical circuit element, the optical circuit element including:
a semiconductor substrate;
a lower cladding layer, a core layer and an upper cladding layer formed above the semiconductor substrate;
a first recess provided in the semiconductor substrate;
second recesses that are provided along the side surfaces of the first recess and are separated from the side surfaces of the first recess;
protrusion portions formed between the first recess and each second recesses; and
an optical waveguide section including the lower cladding layer, the core layer and the upper cladding layer, the optical waveguide section being provided in contact with a side surface that is different from the side surface of the first recess and the side surface opposite the side surface of the first recess; wherein
the surface height of each terrace portion is set at the interface between the second etching stop layer and the second contact layer, and
the height of the top of each protrusion portion is set at the interface between the semiconductor substrate and the lower cladding layer, and
the surface of each terrace portion is contact with the top of each protrusion portion, and
the first etching stop layer and the second etching stop layer are made of different compound semiconductor materials, and the refractive index of the first etching stop layer is higher than the refractive index of the second etching stop layer, and an etching selectivity of the second etching stop layer is higher than the etching selectivity of the first etching stop layer, and
the active layer of the high-mesa section is optically coupled to the core layer of the optical waveguide section.

22. The optical integrated device according to claim 18, wherein
the thickness of the etching stop layer is 0.1 μm or less.

23. The optical integrated device according to claim 19, wherein
the thickness of the etching stop layer is 0.1 μm or less.

24. The optical integrated device according to claim 21, wherein
the first etching stop layer is made of AlInAs, the second etching stop layer is made of AlInAs with a larger Al composition ratio than the first etching stop layer, and the second contact layer is made of InP.

25. The optical integrated device according to claim 16, wherein
the compound semiconductor substrate is made of InP, and the active layer includes a multiple quantum well structure made of InGaAsP having a composition ratio corresponding to a photoluminescence peak wavelength of 1.2 μm or more, or AlGaInAs having a composition ratio corresponding to the photoluminescence peak wavelength of 1.2 μm or more, and the contact layer is made of InP.

26. The optical integrated device according to claim 16, wherein
either one of the tip of the high-mesa section on the side of the optical waveguide section and the tip of the optical waveguide section on the side of the high-mesa section has a spot size converter structure.

27. The optical integrated device according to claim 16, wherein
a first electrode formed on the top surface of the high-mesa section and a second electrode formed on the bottom of the first recess are mechanically and electrically bonded through a conductive bonding member.

28. The optical integrated device according to claim 16, wherein
a distance between the active layer of the high-mesa section and the core layer of the optical waveguide section is 6 μm or less.

29. A method for manufacturing an optical integrated device that integrates an optical functional element and an optical circuit element having a first recess and second recesses, the method for manufacturing an optical integrated device comprising:
a step of manufacturing the optical functional element, the step of manufacturing the optical functional element including: a step of successively epitaxially growing an active layer and a contact layer above a compound semiconductor substrate; a step of forming, by etching, a protruding-shaped high-mesa section that includes a part of the compound semiconductor substrate, the high-mesa section including at least the active layer and the contact layer from the side of the compound semiconductor substrate; and a step of forming terrace portions by wet etching using a mixed solution of tartaric acid and hydrogen peroxide as an etchant, each terrace portion being exposed the outermost surface of the compound semiconductor substrate;
a step of manufacturing the optical circuit element, a step of manufacturing the optical circuit element including: a step of forming a first recess and second recesses separated from the first recess in a semiconductor substrate with a lower cladding layer, a core layer, and an upper cladding layer; and
a step of exposing the uppermost surface of the core layer by selectively removing the upper cladding layer at the top of the protrusion portions formed between the first recess and the second recesses; and
a step of flip-chip mounting the optical functional element and the optical circuit element while making each terrace portion of the optical functional element and the top of each protrusion portion of the optical circuit element contact each other.

30. A method for manufacturing an optical integrated device that integrates an optical functional element and an optical circuit element having a first recess and second recesses, the method for manufacturing an optical integrated device comprising:
a step of manufacturing the optical functional element, the step of manufacturing the optical functional element including: a step of successively epitaxially growing an active layer, an etching stop layer, and a contact layer above a compound semiconductor substrate; a step of forming, by etching, a protruding-shaped high-mesa section that includes a part of the compound semiconductor substrate, the high-mesa section including at least the active layer, the etching stop layer, and the contact layer from the side of the compound semiconductor substrate; and a step of forming terrace portions by dry etching using methane gas as an etching gas, each terrace portion being exposed the outermost surface of the etching stop layer;
a step of manufacturing the optical circuit element, a step of manufacturing the optical circuit element including: a step of forming a first recess and second recesses separated from the first recess in a semiconductor substrate with a lower cladding layer, a core layer, and an upper cladding layer; and
a step of exposing the uppermost surface of the core layer by selectively removing the upper cladding layer at the top of the protrusion portions formed between the first recess and the second recesses; and
a step of flip-chip mounting the optical functional element and the optical circuit element while making each terrace portion of the optical functional element and the top of each protrusion portion of the optical circuit element contact each other.
